(19) United States
(12) Patent Application Publication
(10) Pub. No.: US 2026/0190955 A1
(43) Pub. Date: Jul. 2, 2026

(54) CHIPLET PAIRING TO REDUCE POWER VARIATION

(71) Applicant: MICROSOFT TECHNOLOGY LICENSING, LLC, Redmond, WA (US)

(72) Inventors: Chien-Hui LIAO, Hillsboro, OR (US); Mohammed A. EL-TANANI, Hillsboro, OR (US)

(21) Appl. No.: 19/007,391

(22) Filed: Dec. 31, 2024

(51) Int. Cl. H01L 21/66

(52) U.S. Cl. CPC H10P 74/238

(57) ABSTRACT

The disclosed techniques provide a method for creating a system-on-chip (SoC) integrated circuit (IC). The method includes, for each chiplet, determining a tested leakage power consumption of cores on the chiplet. The pre-binning also includes categorizing the chiplets into categories. The categories are based on the tested leakage power consumption of the chiplets. The categories include a first category and a second category, such that each chiplet that is categorized in the first category has a tested leakage power consumption that is less than a nominal leakage power consumption, and such that each chiplet that is categorized in the second category has a tested leakage power consumption that is greater than the nominal leakage power consumption. The method also includes creating the SoC IC such that the SoC IC includes at least one chiplet from the first category and at least one chiplet from the second category.

### BACKGROUND

Chiplets are modular semiconductor devices that can be combined to create customizable integrated circuits (ICs). Each chiplet is a modular semiconductor die that is designed to operate as part of a larger system. Chiplets provide flexibility and scalability when designing or manufacturing complex ICs. Multi-chiplet ICs can be used in many different applications. For example, multi-chiplet ICs can be used in computing devices in a server rack.

Although multi-chiplet ICs offer a number of technical advantages, these designs still have a number of drawbacks. For example, when using multi-chiplet ICs in computing systems of a datacenter, a high power consumption variance between individual ICs can adversely impact the efficiency of the datacenter. Power is typically allocated to server racks using worst-case power budgets. Due to inherent process variations during manufacturing, some individual chiplets consume significantly more or less power than average. This high variance in IC power consumption leads to a requirement for increased power allocation and increased power capacity for the server rack, exceeding what would be necessary if each chiplet had average power consumption. Increased power allocation and capacity can be achieved by upgrading power distribution units (PDUs), circuit breakers, or other infrastructure components in the datacenter to handle higher wattages.

However, the increased power allocation and capacity required due to the process variations among individual chiplets has the following disadvantages. An increased cost in datacenter infrastructure is typically required, and the infrastructure may take up more physical space in the datacenter. Also, there may be reduced energy efficiency and increased power consumption. Also, there may be more waste heat that must be removed through cooling. In large-scale deployments, these inefficiencies can compound, leading to significant economic and environmental consequences.

### SUMMARY

To address the above-described issues, the disclosed techniques provide a method for creating integrated circuits (ICs) from individual chiplets in such a way that power variation among the ICs is reduced. The method is accomplished by first using test equipment to determine, for each chiplet, the total leakage power consumption (P_{LEAKAGE}) of the chiplet or the operating speed of the chiplet. After each chiplet is tested, individual chiplets are categorized based on the tested total leakage power consumption P_{LEAKAGE} of the chiplet.

For example, in one embodiment, each chiplet is placed into one of two categories: a “slow” category or a “fast” category. In this embodiment, the two categories are based on whether a chiplet has a tested total leakage power consumption P_{LEAKAGE} (or operating speed) that is less than or greater than a nominal leakage power consumption that is known. More specifically, in this embodiment, a chiplet that has a tested total leakage power consumption P_{LEAKAGE} (or operating speed) that is less than the nominal leakage power consumption is placed in the slow category, and a chiplet that has a tested total leakage power consumption P_{LEAKAGE} (or operating speed) that is greater than the nominal leakage power consumption is placed in the fast category.

After the chiplets are tested and categorized, an assembly system creates the ICs by pairing the chiplets. The assembly system creates each IC by packaging together two or more chiplets from the appropriate categories. For example, the two chiplets packaged together are selected from categories so that the tested total leakage power consumption P_{LEAKAGE} (or operating speed) of the chiplets are balanced against each other (relative to the nominal leakage power consumption). This can result in an IC that is assembled by packaging together one chiplet from the slow category and one chiplet from the fast category.

The ICs created in this way have a significantly reduced power variation relative to ICs created without categorizing the chiplets. Because the power variation is reduced, server racks in datacenters that use computing devices with ICs created in this way can use reduced power allocation and capacity.

The reduced power allocation and capacity that is possible using ICs created in this way has the following advantages. The infrastructure cost may be reduced, and the infrastructure to take up less space in the datacenter. Also, there may be increased energy efficiency, decreased power consumption, and less cooling needed.

The ICs created in this way also achieve lower dynamic power variability when voltage-frequency searching techniques are performed for supply voltage rails in the IC that are dominated by dynamic power consumption.

Additionally, creating ICs in this way may increase the yield rate. The yield rate is the percentage of manufactured devices that meet all specifications and function as intended. Using conventional techniques, there are some ICs or chiplets that do not meet all specifications and are scrapped, for example because both chiplets are slow relative to nominal speed, and therefore the overall operating speed of the IC is too slow to meet the specifications. However, by pairing fast chiplets with slow chiplets, slower chiplets do not have to be scrapped and do not result in an IC that fails to meet the specifications.

### BRIEF DESCRIPTION OF THE DRAWINGS

The Detailed Description is described with reference to the accompanying figures. In the figures, the left-most digit(s) of a reference number identifies the figure in which the reference number first appears. The same reference numbers in different figures indicate similar or identical items. References made to individual items of a plurality of items can use a reference number with a letter of a sequence of letters to refer to each individual item. Generic references to the items may use the specific reference number without the sequence of letters.

FIG. 1 shows a functional block diagram illustrating an embodiment of a process for creating a system-on-chip (SoC) Integrated Circuit (IC) with reduced power variation.

FIG. 2 illustrates an embodiment of the test equipment of FIG. 1 testing a chiplet for total leakage power consumption by measuring leakage current.

FIG. 3 illustrates an embodiment of the test equipment of FIG. 1 testing a chiplet for total leakage power consumption by measuring an oscillation frequency of a ring oscillator.

FIG. 4A shows a first chiplet being tested for total leakage power consumption.

FIG. 4B shows the first chiplet of FIG. 4A being placed in a first bin.

FIG. 4C shows a second chiplet being tested for total leakage power consumption.

FIG. 4D shows the second chiplet being placed in the first bin.

FIG. 4E shows a third chiplet being tested for total leakage power consumption.

FIG. 4F shows the third chiplet being placed in the first bin.

FIG. 4G shows a fourth chiplet being tested for total leakage power consumption.

FIG. 4H shows the fourth chiplet being placed in a second bin.

FIG. 4I shows an SoC IC being assembled from a chip package, the first chiplet, and the fourth chiplet.

FIG. 5 shows an embodiment of the process of FIG. 1 in which there are four bins and two categories.

FIG. 6A shows an embodiment of the process of FIG. 1 in which the SoC IC is assembled to include one chiplet from a moderately slow category and one chiplet from a moderately fast category.

FIG. 6B shows an example of the process of FIG. 6A in which the SoC IC is assembled to include one chiplet from a very slow category and one chiplet from a very fast category.

FIG. 7A shows an embodiment of the process of FIG. 6A in which there are five bins.

FIG. 7B shows an embodiment of the process of FIG. 7A in which the SoC IC is assembled from two nominal speed chiplets.

FIG. 7C shows an embodiment of the process of FIG. 6B in which there are five bins.

FIG. 8A shows an embodiment of the process of FIG. 1 in which there are nine bins and the SoC IC is assembled from one chiplet from the fourth bin and one chiplet from the sixth bin.

FIG. 8B shows an embodiment of the process of FIG. 8A in which the SoC IC is assembled from two chiplets from the fifth bin.

FIG. 8C shows an embodiment of the process of FIG. 8A in which the SoC IC is assembled from one chiplet from the third bin and one chiplet from the seventh bin.

FIG. 8D shows an embodiment of the process of FIG. 8A in which the SoC IC is assembled from one chiplet from the second bin and one chiplet from the eighth bin.

FIG. 8E shows an embodiment of the process of FIG. 8A in which the SoC IC is assembled from one chiplet from the first bin and one chiplet from the ninth bin.

FIG. 9 shows a functional block diagram of an embodiment of the process of FIG. 1 in which the SoC IC has four chiplets.

FIG. 10 illustrates a block diagram of an embodiment of a server rack that is balanced with respect to leakage power consumption.

FIG. 11 is a flow diagram showing an embodiment of a process for creating an SoC IC.

FIG. 12 illustrates a block diagram of an embodiment of a system for creating an SoC IC with reduced power variation.

FIG. 13 is a computer architecture diagram illustrating a computing device architecture for a computing device capable of implementing aspects of the techniques and technologies presented herein.

### DETAILED DESCRIPTION

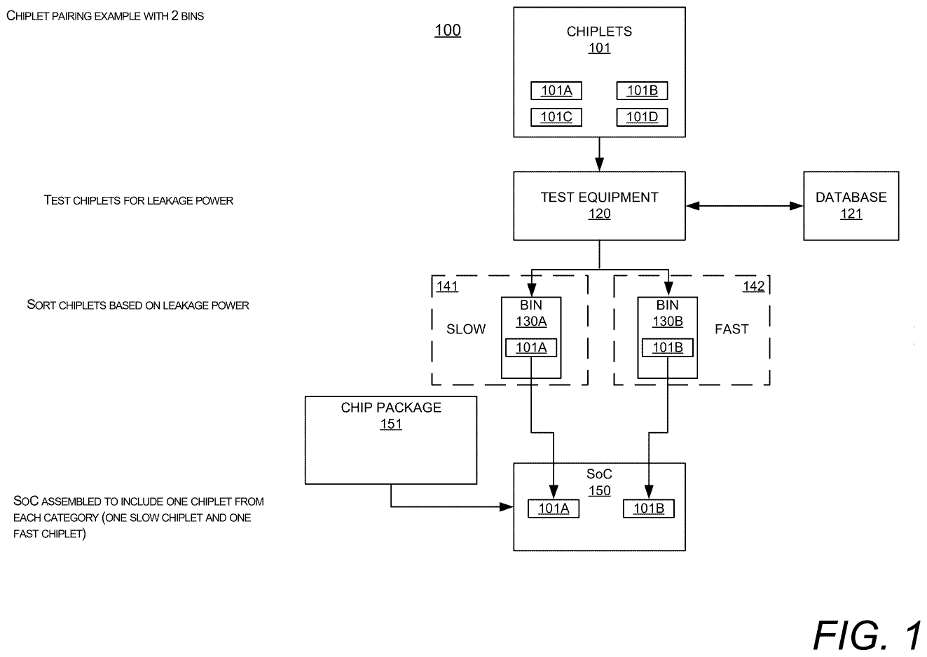

FIG. 1 shows a functional block diagram illustrating an embodiment of a process 100 for creating a system-on-chip (SoC) Integrated Circuit (IC) (150) with reduced power variation. The process 100 uses chiplets 101, which may include individual chiplets such as a first chiplet 101A, a second chiplet 101B, a third chiplet 101C, and a fourth chiplet 101D. A chiplet 101 is a semiconductor die that can be combined with another chiplet to create a more complex IC, such as the SoC IC 150. Each of the chiplets 101 includes one or more cores.

The chiplets 101 are provided to test equipment 120. The test equipment 120 is configured to test the chiplets 101 determine, for each chiplet 101, either the total leakage power consumption or the operating speed of each of the cores on the chiplet 101. The test equipment 120 is used to determine the total leakage power leakage power consumption or the operating speed for each of the chiplets 101 using substantially the same operating conditions for each chiplet 101. These operating conditions may include, for example, the supply voltage of each of the cores on the chiplets and ambient temperature. In some embodiments, different cores have different supply voltages. The test equipment 120 may be communicatively coupled to a database 121, which stores information related to the testing process, results of the testing, and other relevant data.

The chiplets 101 are tested for total leakage power consumption (or operating speed) relative to a known nominal operating speed or nominal leakage power consumption of the chiplets 101. The operating speed of each chiplet 101 has a strong correlation to total leakage power consumption of the chiplet 101. For this reason, the techniques herein treat the operating speed of a chiplet and the total leakage power consumption of that chiplet as being equivalent to each other.

The chiplets 101 are then sorted into different bins 130 according to the total leakage power consumption (or operating speed) of the chiplets 101. In the example shown, there are two bins 130: a first bin 130A for chiplets having a total leakage power consumption (or operating speed) that is less than the nominal leakage power consumption, and a second bin 130B for chiplets having a total leakage power consumption (or operating speed) than is greater than the nominal total leakage power consumption (or operating speed). The first bin 130A is in the slow category 141 and the second bin 130B is in the fast category 142. The chiplets placed in the first bin 130A are categorized as slow 141 because the chiplets placed in the first bin 130A have an operating speed that is less than the nominal operating speed. Similarly, the chiplets placed in the second bin 130B are categorized as fast 142 because the chiplets placed in the second bin 130B have an operating speed that is greater than the nominal operating speed. Information that is associated with sorting the chiplets 101 into bins is stored in the database 121. In the example shown, the first chiplet 101A is placed in the first bin 130A, and the second chiplet 101B is placed in the second bin 130B. In some embodiments, the database 121 stores information that indicates, for each chiplet, the bin into which the chiplet has been placed.

In general, the binning discussion herein will refer to leakage power consumption, however, as discussed above, it will be understood that in some embodiments, binning may instead be performed based on operating speed or dynamic power consumption rather than leakage power consumption.

In some embodiments, the sorting of the chiplets 101 into the bins 130 is performed by a software-based process that is executed on one or more processors. In some embodiments, the one or more processors that perform the sorting of the chiplets 101 into the bins 130 are part of the test equipment 120.

The sorting of the chiplets 101 into the bins 130 shown in FIG. 1 is an example of pre-binning. The “pre-binning” of chiplets refers to sorting chiplets into bins prior to assembling the chiplets into an IC.

After the pre-binning is performed, the SoC IC 150 is assembled from a chip package 151 and two chiplets. The term “chip package” refers to all of the components of the SoC IC other than the chiplets. For instance, in some embodiments, the chip package 151 includes a unifying substrate; an interposer; encapsulation material; passive components such as resistors, capacitors, and inductors; and external connectors such as solder balls, pins, or pads; or other suitable components. For example, the assembly of the SoC IC 150 may include interconnecting the two chiplets using packaging techniques, encapsulating the two chiplets in a protective material, and equipping the SoC IC 150 with external components that enable the SoC IC 150 to interface with other elements.

In some embodiments, an assembly system in a cleanroom environment assembles the SoC IC 150 from the chip package 151 and two chiplets. In some embodiments, the assembly system includes automated handling equipment, a die bonding, a wire bonding machine, an encapsulation system, or other suitable equipment.

In the illustrated embodiment, the two chiplets from which the SoC IC 150 is assembled are, more specifically, one chiplet (e.g., the first chiplet 101A) from the slow category 141 and one chiplet (e.g., the second chiplet 101B) from the fast category 142. By assembling the SoC IC 150 with one chiplet from the slow category 141 and one chiplet from the fast category 142, the SoC IC 150 may have significantly reduced power distribution variance relative to an SoC IC created from two random chiplets. Because the power distribution variance is reduced, server racks that use SoC ICs created in this way can use reduced power allocation and capacity. Additionally, as discussed above, creating SoC ICs in this way may increase the yield rate.

Previous techniques may assemble an IC that pairs a chiplet with a fast operating speed with another chiplet with a fast operating speed. This may result in an IC with a good operating speed, but which may require increased power allocation and capacity. By instead assembling an IC in which the chiplets are balanced against each other relative to the nominal operating speed, power allocation and capacity may be significantly reduced while also increasing the yield rate.

If, instead, an IC were assembled by pairing a chiplet with a slow operating speed with another chiplet with a slow operating speed, this may result in an IC with lower power consumption, but the overall operating speed of the IC would be slow. By instead assembling an IC in which the chiplets are balanced against each other relative to the nominal operating speed, a lower variance in the power consumption and in the performance of the ICs may be achieved, and chiplets with different operating speeds are all put to good use.

As discussed above, previous techniques may be used to assemble ICs having a particular operating speed. For example, previous techniques may pair two chiplets that each have a fast operating speed in order to create an IC with a fast operating speed. In contrast, some embodiments of the process 100 are effective for creating ICs (e.g., the SoC IC 150) that do not differentiate between the various possible operating speeds of the ICs.

It may be appreciated that while FIG. 1 shows a specific embodiment that uses two bins, any suitable number of bins may be used in various embodiments. Several different embodiments that use various numbers of bins are discussed in greater detail below.

In some embodiments, the test equipment 120 includes an Automatic Test Equipment (ATE) unit suitable for measuring various parameters associated with the chiplets 101 and other electronic devices. The ATE unit may include hardware components such as power supplies, signal generators, and measurement instruments, as well as software to control the testing process and analyze the results. In various embodiments, the test equipment 120 determines the total leakage power for each of the chiplets 101 in different suitable ways.

For example, in some embodiments, the test equipment 120 measures leakage current for each core in the chiplet 101 and determines the total leakage power consumption of the chiplet using the measured leakage currents. In other embodiments, the test equipment 120 or on-die measurements tools measure the frequency of an on-chip ring oscillator in the chiplet 101 and determine the operating speed, rather than the leakage current, of the chiplet using the measured frequency. In yet other embodiments, the test equipment 120 determines the total leakage power consumption of the chiplets in other suitable ways.

In some embodiments of the process 100, some chiplets 101 have multiple supply voltage rails, and each core on the chiplet 101 has its own separate supply voltage rail. In some embodiments in which each core has its own separate supply voltage rail, the leakage power consumption is determined separately for each core based on the supply voltage of that core. In other embodiments, the chiplet is modeled as having the same supply voltage for each core, and the total leakage power consumption of the chiplet is determined based on the modeled supply voltage.

As discussed above, in some embodiments, each of the chiplets 101 includes multiple supply voltage rails. Some embodiments of the process 150 are effective for creating ICs (e.g., the SoC IC 150) in which, for some of the supply voltage rails, the components supplied power by the supply voltage rail have a higher leakage power consumption contribution.

In some embodiments of the SoC IC 150 that include multiple supply voltage rails in which some of the supply voltage rails are dominated by dynamic power consumption and some of the supply voltage rails are dominated by leakage power consumption, the chiplet pairing discussed above also achieves lower dynamic power variability when voltage-frequency searching techniques are performed for the supply voltage rails dominated by dynamic power consumption. “Voltage-frequency searching” techniques are techniques used to determine the optimal combination of voltage and clock frequency for each core to maximize performance while minimizing power consumption, particularly for dynamic-power-heavy regions.

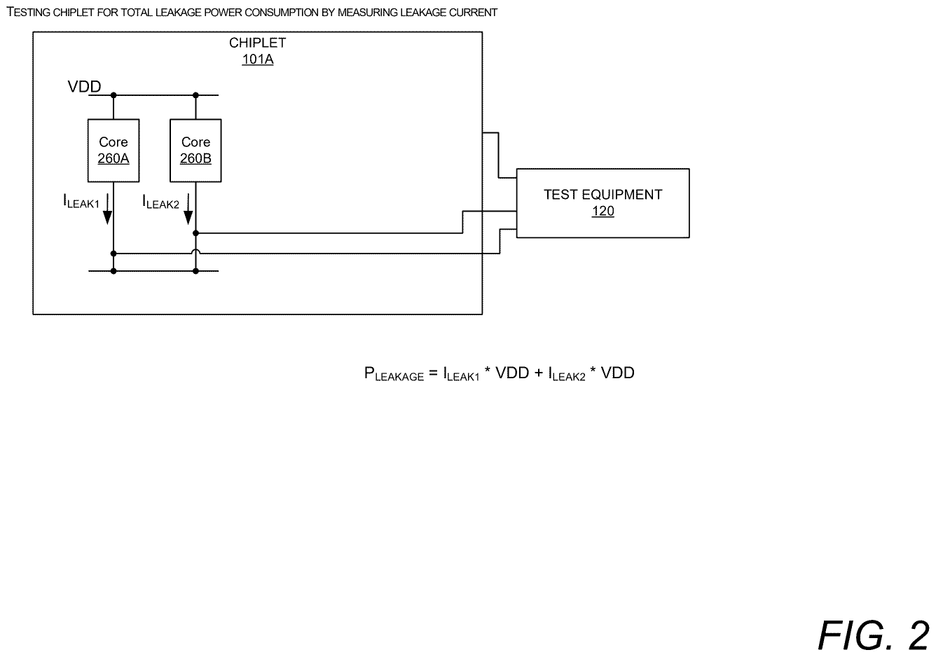

FIG. 2 illustrates an embodiment of the test equipment 120 testing the first chiplet 101A for total leakage power consumption by measuring leakage current. The first chiplet 101A includes one or more cores 260. For instance, in some embodiments, the first chiplet 101A includes a first core 260A and a second core 260B.

The test equipment 120 measures the leakage current of each of the cores 260 on the first chiplet 101A. This is accomplished as follows in some embodiments. First, the chiplet 101A is powered up. When powered up, the chiplet 101A provides a supply voltage VDD to each of the cores 260. Next, the test equipment 120 provides an appropriate input to place the chiplet 101A in a mode for measuring leakage current. The mode for measuring leakage current may include disabling normal switching activity in the chiplet 101A and enabling dedicated current-monitoring circuits. In various embodiments, the current-monitoring circuits may be on the first chiplet 101A or on the test equipment 120. Each of the cores 260 is isolated, and all of the logic gates in the cores 260 are held stable with no switching. Next, the current-monitoring circuits monitor each of the cores 260 for steady-state current. Because there is no dynamic switching activity, these steady-state currents contain only the leakage current. In this way, the first leakage current I_{LEAK1} of the first core 260A and the second leakage current I_{LEAK2} of the second core 260B are measured.

The leakage power consumption of each of the cores 260 is calculated by multiplying the leakage current by the supply voltage VDD. The total leakage power consumption for all of the cores 260 is calculated by adding together the leakage power consumption of each of the cores 260. For example, in the case of two cores 260, the total leakage power consumption P_{LEAKAGE}=I_{LEAK1}*VDD+I_{LEAK2}*VDD.

It will be appreciated that many suitable variations and refinements of this basic process can be utilized, which is provided by way of explanation and example only. For instance, in some embodiments, multiple readings can be taken and averaged together in order to improve accuracy.

Although FIG. 2 shows the same supply voltage VDD being provided to each of the cores 260, it will be appreciated that, in some embodiments, different cores use different supply voltages. For instance, in the case of two cores 260A and 260B each having a separate supply voltage (VDD1 and VDD2 respectively), the total leakage power consumption P_{LEAKAGE}=I_{LEAK1}*VDD1+I_{LEAK2}*VDD2.

The operating speed and the total leakage power consumption of a chiplet can vary greatly depending on operating conditions such as the ambient temperature and the supply voltage provided to each of the cores. For this reason, when testing each of the chiplets 101, the operating conditions that may influence the results, such as the ambient temperature and the supply voltage provided to each of the cores, are kept the same for the testing of each of the chiplets 101.

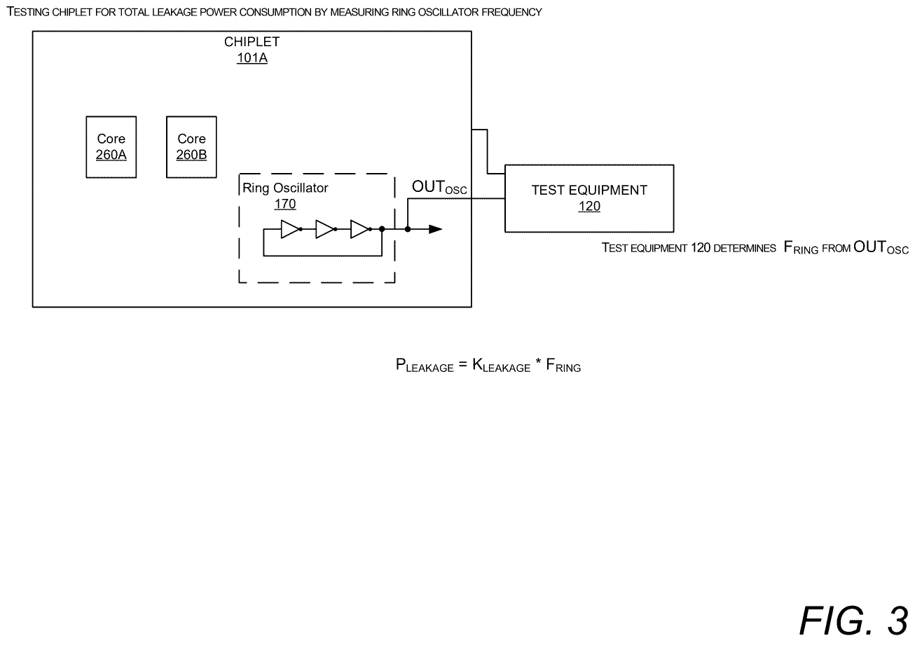

FIG. 3 illustrates an embodiment of the test equipment 120 testing the first chiplet 101A for operating speed by measuring an oscillation frequency (F_{RING}) of a ring oscillator 170 on the first chiplet 101A. The ring oscillator 170 is an embedded on-chip oscillator that is created using the same process as other components in the first chiplet 101A such as the cores 260.

The test equipment 120 or on-die measurement tools determine the ring oscillator output signal OUT_{OSC}. Next, the test equipment 120 receives the ring oscillator output signal OUT_{OSC} and processes the ring oscillator output signal OUT_{OSC} to determine the oscillation frequency F_{RING} of the ring oscillator 170. For example, in some embodiments, a frequency counter in the test equipment 120 counts transitions over a determined time interval to determine the oscillation frequency F_{RING} of the ring oscillator 170. In other embodiments, a waveform analyzer in the test equipment 120 analyzes the waveform of the ring oscillator output signal OUT_{OSC} directly to determine the oscillation frequency F_{RING} of the ring oscillator 170. In some embodiments, multiple readings of the oscillation frequency F_{RING} of the ring oscillator 170 are taken in order to ensure an accurate reading.

After determining the oscillation frequency F_{RING} of the ring oscillator 170, the test equipment 120 calculates the operating speed of the chiplet 101. Alternatively, in some embodiments, rather than converting the oscillation frequency F_{RING} of the ring oscillator 170 into the operating speed, the oscillation frequency F_{RING} of the ring oscillator 170 can be used directly, with the bins and categories being based directly upon the oscillation frequency F_{RING} of the ring oscillator 170 rather than the total leakage power consumption.

The operating speed of a chiplet and the oscillation frequency F_{RING} of the ring oscillator 170 can vary greatly depending on operating conditions such as the ambient temperature and the supply voltage provided to each of the cores. For this reason, when testing each of the chiplets 101, the operating conditions that may influence the results, such as the supply voltage provided to the ring oscillator 170 and the ambient temperature, are kept the same for the testing of each of the chiplets 101.

FIG. 3 illustrates ring oscillator 170 as a ring oscillator composed of three inverters. However, it will be appreciated that other suitable ring oscillator architectures may be used in other embodiments.

In various embodiments, the techniques discussed and shown herein determine the total leakage power consumption of a chiplet (or the operating speed of the chiplet) using the process illustrated in FIG. 2, using the process illustrated in FIG. 3, or in another suitable way. For instance, in some embodiments, the total leakage power consumption is determined by fabricating a proxy on the chiplet other than a ring oscillator and measuring the speed of the proxy. In these embodiments, the proxy is a circuit on the chiplet that uses the same manufacturing process and materials as the other components on the chiplet, and which is specifically designed to mimic the behavior of the processing units and to provide an easily measurable metric that allows for an accurate estimation of the total leakage power consumption of the chiplet. For instance, in some embodiments, the proxy is a set of logic gates designed specifically for measurement purposes. In other embodiments, other suitable proxies are used.

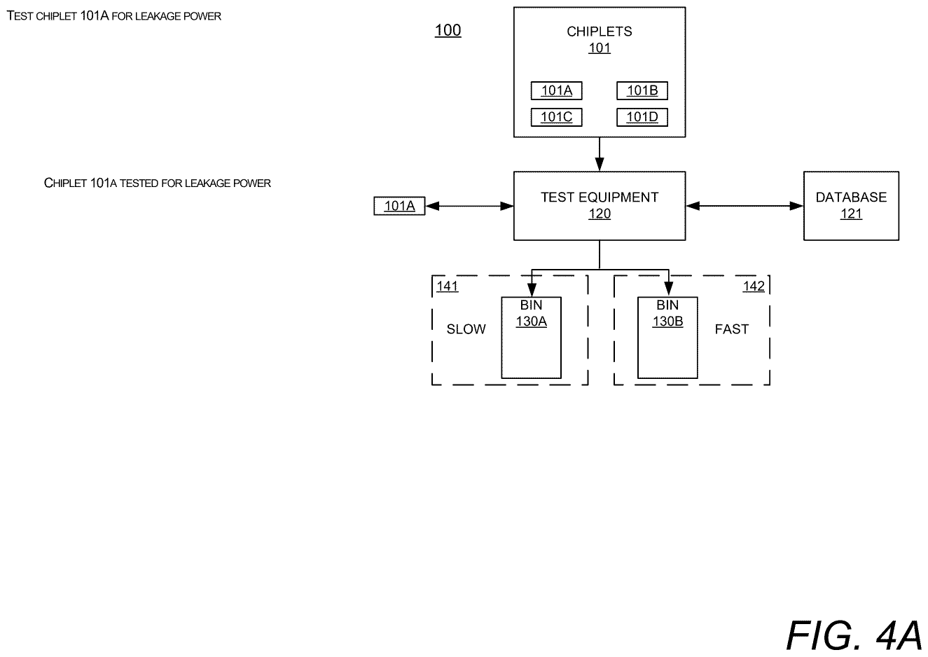

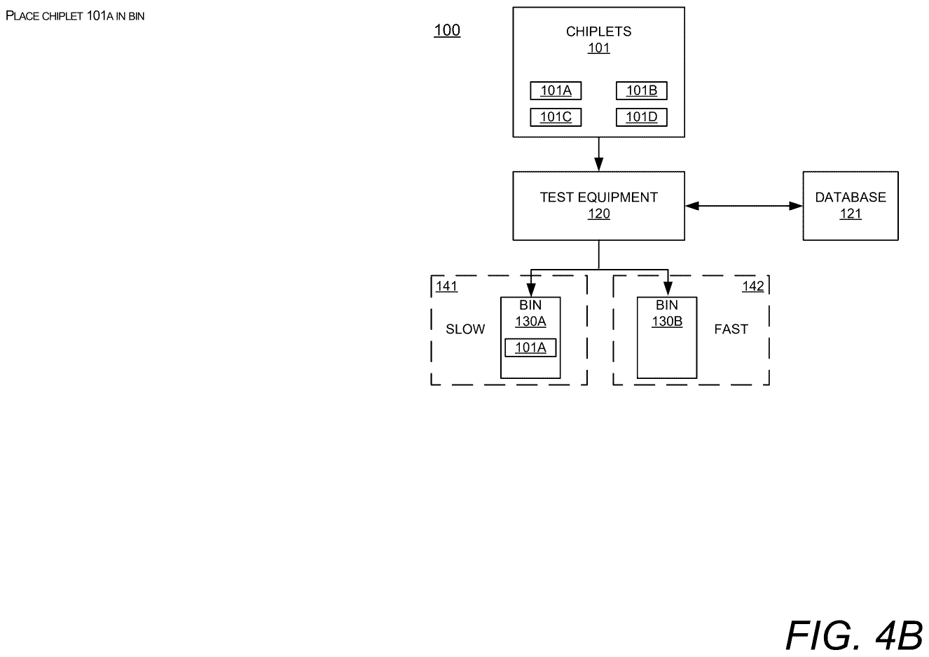

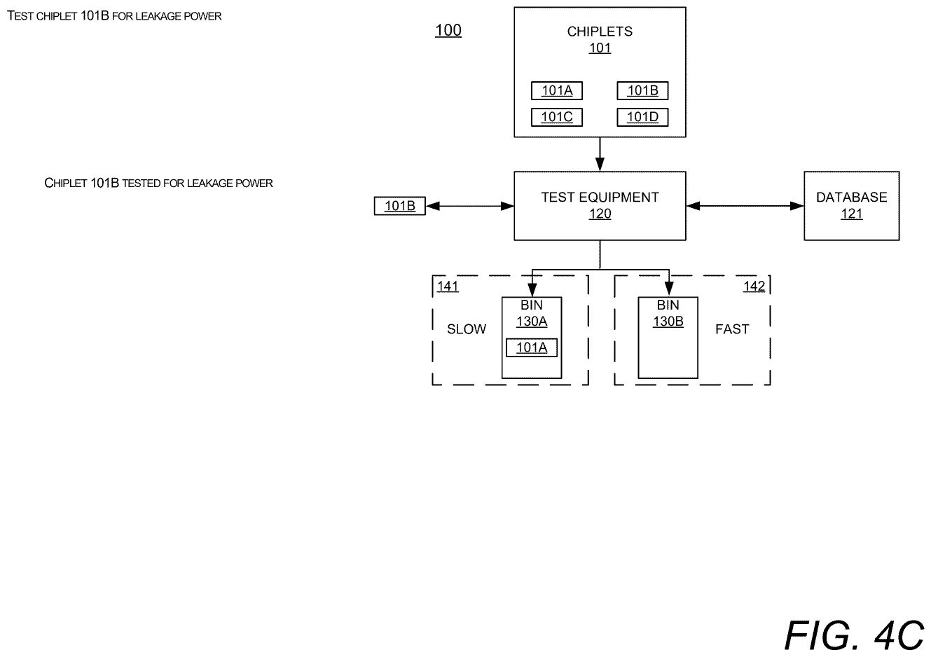

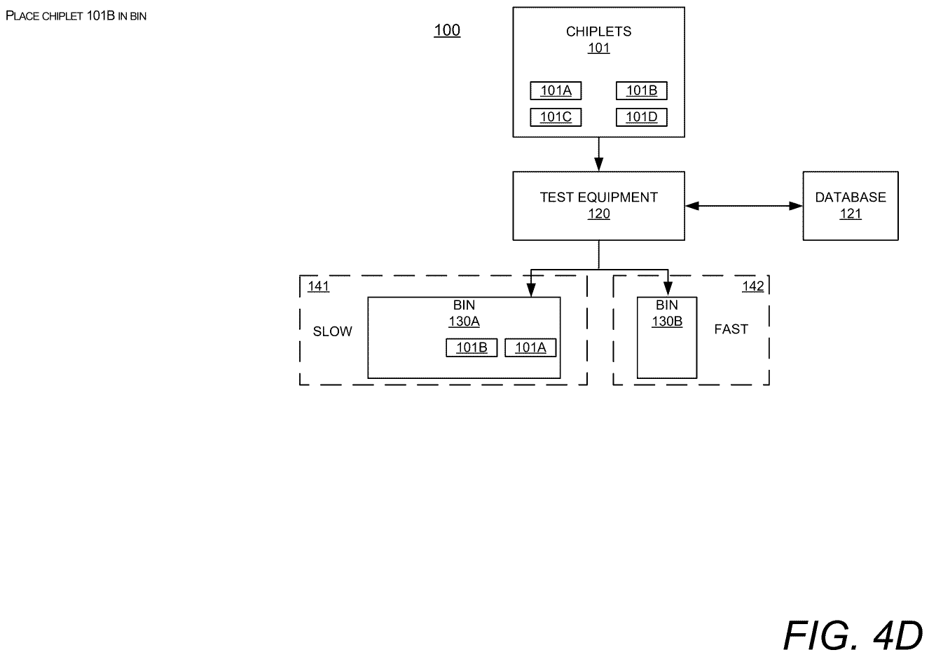

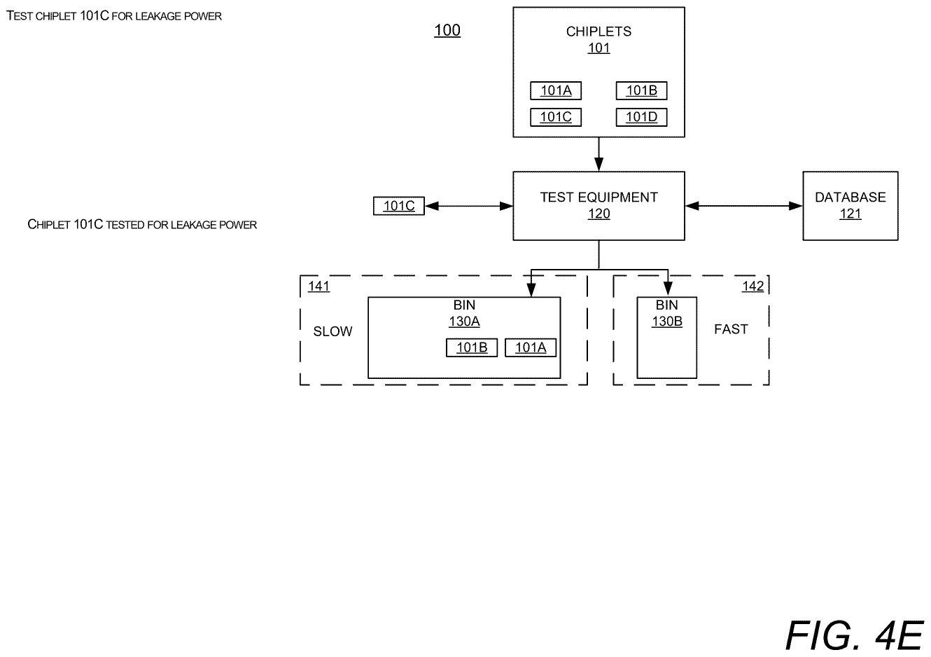

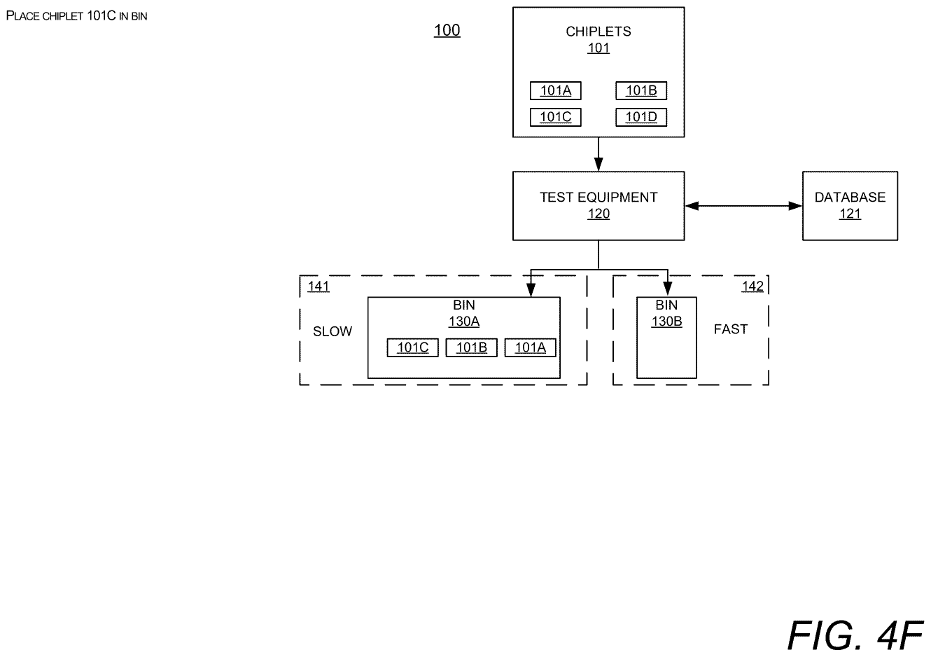

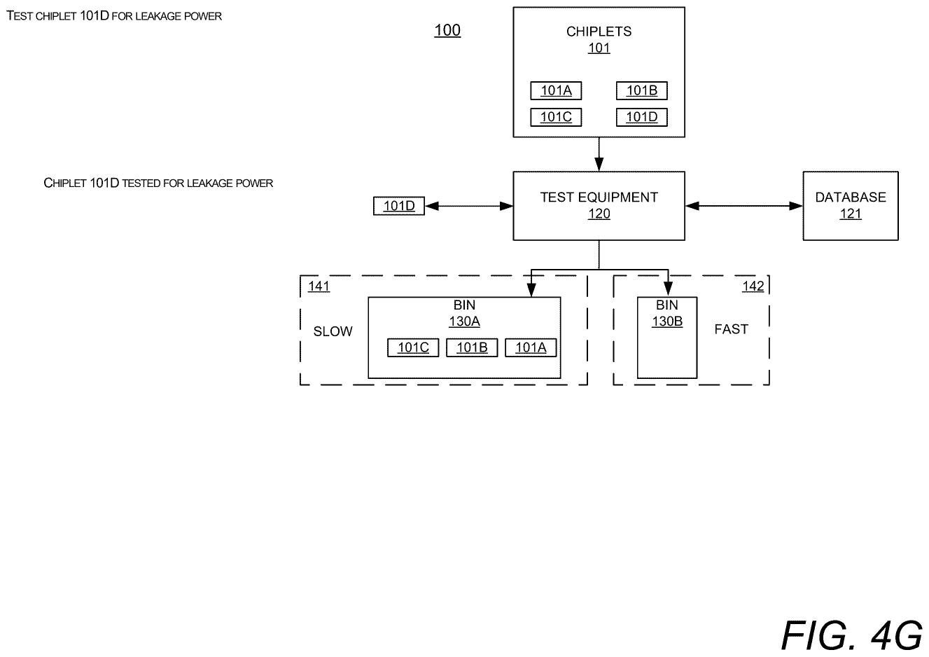

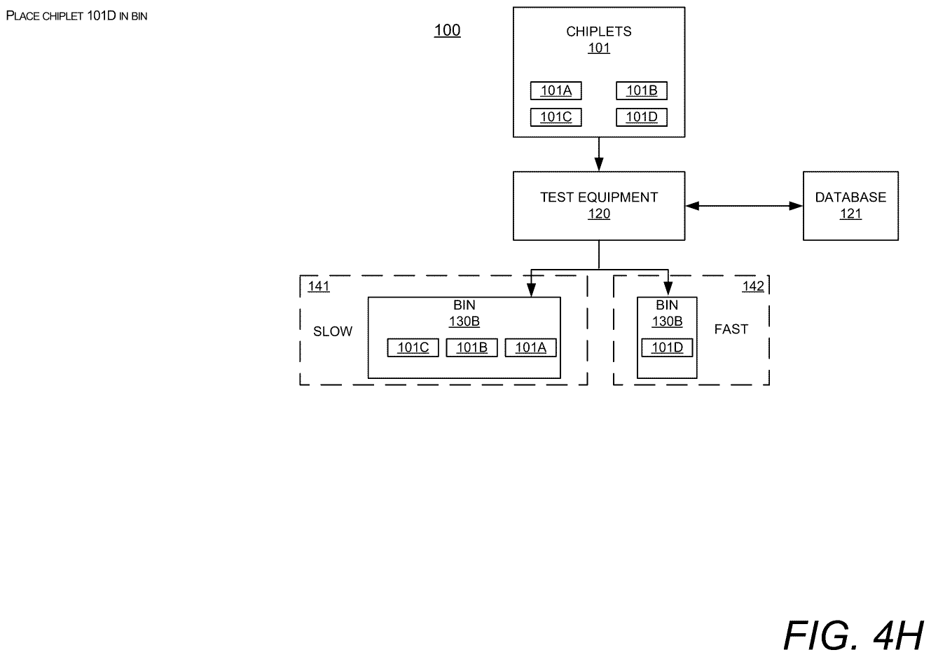

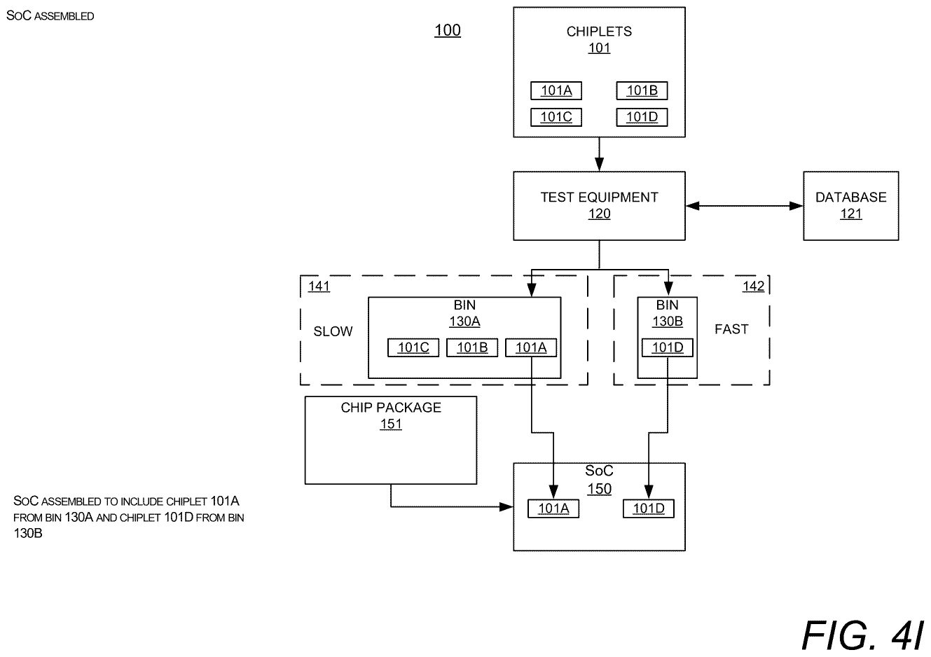

FIGS. 4A-4I show a step-by-step example of an embodiment of the process 100 of FIG. 1.

As shown in FIG. 4A, the test equipment 120 tests the first chiplet 101A for total leakage power consumption. When the testing of the first chiplet 101A is completed, the test equipment 120 determines the total leakage power consumption of the first chiplet 101A. The database 121 stores information about the testing of the first chiplet 101A, including the total leakage power consumption of the first chiplet 101A. The actual nominal total leakage power consumption of a chiplet can vary greatly depending on the manufacturing process used, transistor size, and many other factors.

FIG. 4B shows the first chiplet 101A being placed in the first bin 130A. In the embodiment shown, each chiplet that is determined to have a total leakage power consumption that is less than the nominal total leakage power consumption is placed in the first bin 130A. The first chiplet 101A was determined to have a total leakage power consumption that is less than the nominal total power consumption.

FIG. 4C shows the second chiplet 101B being tested for total leakage power consumption by the test equipment 120. When the testing of the second chiplet 101B is completed, the test equipment 120 determines the total leakage power consumption of the second chiplet 101B. The database 121 stores information about the testing of the second chiplet 101B, including the total leakage power consumption of the second chiplet 101B.

FIG. 4D shows the second chiplet 101B being placed in the first bin 130A. The second chiplet 101B was determined to have a total leakage power consumption that is less than the nominal total power consumption.

FIG. 4E shows the third chiplet 101C being tested for total leakage power consumption by the test equipment 120. When the testing of the third chiplet 101C is completed, the test equipment 120 determines the total leakage power consumption of the third chiplet 101C. The database 121 stores information about the testing of the third chiplet 101C, including the total leakage power consumption of the third chiplet 101C.

FIG. 4F shows the third chiplet 101C being placed in the first bin 130A. The third chiplet 101C was determined to have a total leakage power consumption that is less than the nominal total power consumption.

FIG. 4G shows the fourth chiplet 101D being tested for total leakage power consumption by the test equipment 120. When the testing of the fourth chiplet 101D is completed, the test equipment 120 determines the total leakage power consumption of the fourth chiplet 101D. The database 121 stores information about the testing of the fourth chiplet 101D, including the total leakage power consumption of the fourth chiplet 101D.

FIG. 4H shows the fourth chiplet 101D being placed in the second bin 130B. In the embodiment shown, each chiplet 101 that is determined to have a total leakage power consumption that is greater than the nominal total leakage power consumption is placed in the second bin 130B. The fourth chiplet 101D was determined to have a total leakage power consumption that is greater than the nominal total power consumption.

FIG. 4I shows the SoC IC 150 being assembled from the chip package 151 and two chiplets: one chiplet (e.g., the first chiplet 101A) from the slow category 141 and one chiplet (e.g., the fourth chiplet 101D) from the fast category 142.

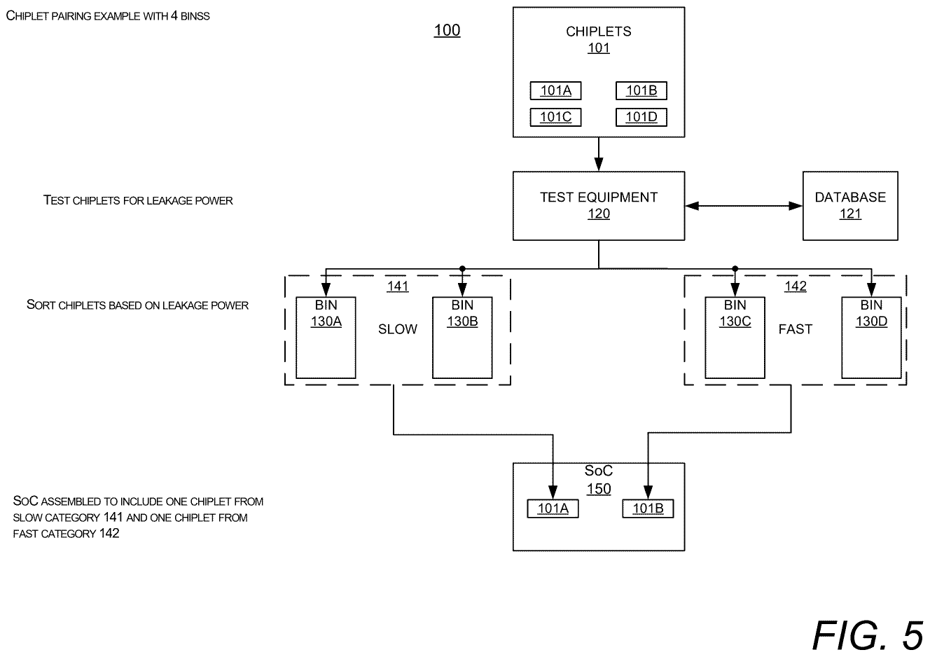

FIG. 5 shows an example of the process 100 in which there are a total of four bins 130: a first bin 130A, a second bin 130B, a third bin 130C, and a fourth bin 130D. The first and second bins 130A and 130 B are used for chiplets with an operating speed that is less than nominal speed, with chiplets in the first bin 130A being used for chiplets with an even slower operating speed than chiplets in the second bin 130B. The third and fourth bins 130C and 130D are used for chiplets with an operating speed that is greater than nominal speed, with chiplets in the fourth bin 130D being used for chiplets with an even faster operating speed than chiplets in the third bin 130C.

In the embodiment shown in FIG. 5, chiplets in the first bin 130A and the second 130B are categorized as belonging to the slow category 141, and chiplets in the third bin 130C and the fourth bin 130D are categorized as belonging to the fast category 142. Although there are more bins than in the embodiment of FIG. 1, just as in the embodiment of FIG. 1, after the pre-binning, the SoC IC 150 is assembled with two chiplets: one chiplet (e.g., the first chiplet 101A) from the slow category 141 and one chiplet (e.g., the second chiplet 101B) from the fast category 142.

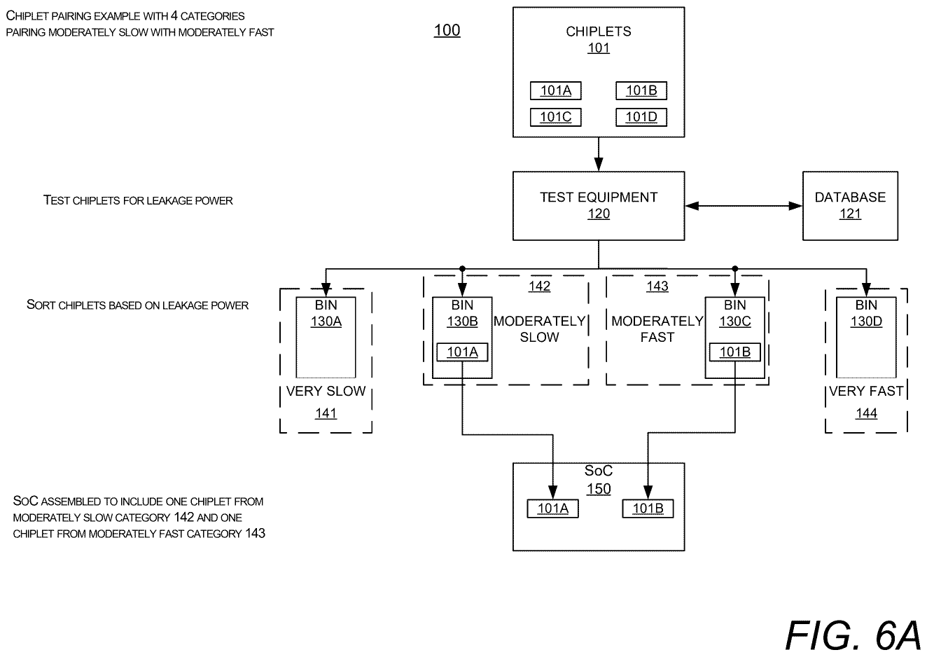

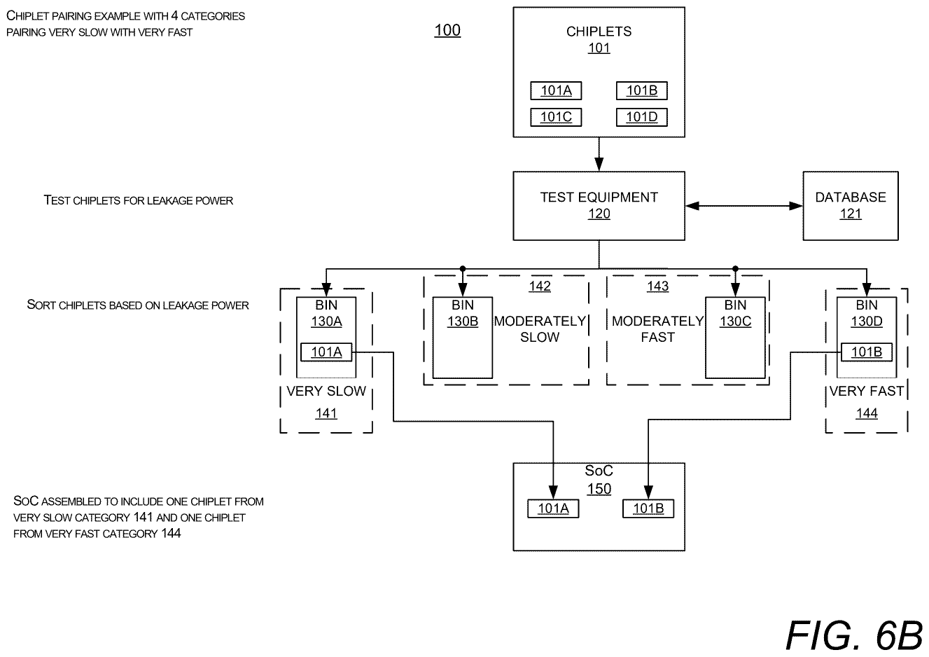

FIG. 5 shows an embodiment of the process 100 in which there are four bins and two categories, with two bins from each category. However, numerous other suitable permutations of bins and categories are used in various embodiments of the process 100. For instance, FIGS. 6A-6B show an embodiment of the process 100 that is similar to the embodiment of FIG. 5 except that each of the four bins is its own category, so that there are four bins and four categories, with one bin for each category. In FIGS. 6A and 6B, there are four categories: a very slow category 141, a moderately slow category 142, a moderately fast category 143, and a very fast category 144. The very slow category 141 includes the first bin 130A, the moderately slow category 142 includes the second bin 130B, the moderately fast category 143 includes the third bin 130C, and the very fast category 130D includes the fourth bin 130D.

In the embodiment shown in FIGS. 6A-6B, just like in the embodiment shown in FIG. 4, the chiplets that have a very slow operating speed relative to nominal speed are placed in the first bin 130A, the chiplets that have a moderately slow operating speed relative to nominal speed are placed in the second bin 130B, the chiplets that have a moderately fast operating speed relative to nominal speed are placed in the third bin 130C, and the chiplets that have a very fast operating speed relative to the nominal speed are placed in the fourth bin 130D. In the embodiment shown in FIGS. 6A-6B, just as in the embodiment shown in FIG. 4, the bin placement of each chiplet is determined according to the tested total leakage power consumption of the chiplet.

Whereas the embodiment shown in FIG. 4 uses two categories (a slow category and a fast category), the embodiment shown in FIGS. 6A-6B uses four categories (the very slow category 141, the moderately slow category 142, the moderately fast category 143, and the very fast category 144). In the embodiment shown in FIGS. 6A-6B, the SoC IC 150 is formed by pairing two chiplets: either (1) one chiplet from the moderately slow category 142 and one chiplet from the moderately fast category 143, or (2) one chiplet from the very slow category 141 and one chiplet from the very fast category 144. More specifically, FIG. 6A shows an example of the process 100 in which the SoC IC 150 is assembled to include one chiplet (the first chiplet 101A) from the moderately slow category 142 and one chiplet (the second chiplet 101B) from the moderately fast category 143. FIG. 6B shows an example of the process 100 in which the SoC IC 150 is assembled to include one chiplet (the first chiplet 101A) from the very slow category 141 and one chiplet (the second chiplet 101B) from the very fast category 144.

By pairing moderately slow chiplets with moderately fast chiplets and pairing very slow chiplets with very fast chiplets, power distribution variance in the SoC IC 150 is reduced. In essence, the more categories there are, the finer the pairing can be, and the lower the power distribution variance.

In each case, the categories are preferably symmetrical with respect to the nominal operating speed of the chiplets. That is, for every category, there exists a corresponding category that balances that category with respect to nominal operating speed. When assembling the SoC IC, when the SoC IC includes one chiplet from a particular category, the other chiplet is selected from the corresponding category that balances that category with respect to nominal operating speed. For instance, in FIG. 6A, the moderately slow category 142 and the moderately fast category 143 are symmetrical with respect to the nominal operating speed of the chiplets. That is, the range of operating speeds for chiplets in the moderately slow category 142 and the range of operating speed for chiplets in the moderately fast category 143 are symmetric with respect to the nominal operating speed.

In some examples, the moderately slow category 142 has a corresponding category, moderately fast category 143, that balances the moderately slow category 142 with respect to the nominal operating speed. In this way, when assembling the SoC IC, when the SoC IC includes one chiplet the moderately slow category 142, the other chiplet is selected from the corresponding category that balances that category with respect to the nominal operating speed, which is the moderately fast category 143. If there is a category for nominal operating speed, the corresponding category for the nominal operating speed category is that same category. When assembling the SoC IC, when the SoC IC includes one chiplet from a nominal operating speed category, the other chiplet is also selected from the nominal operating speed category.

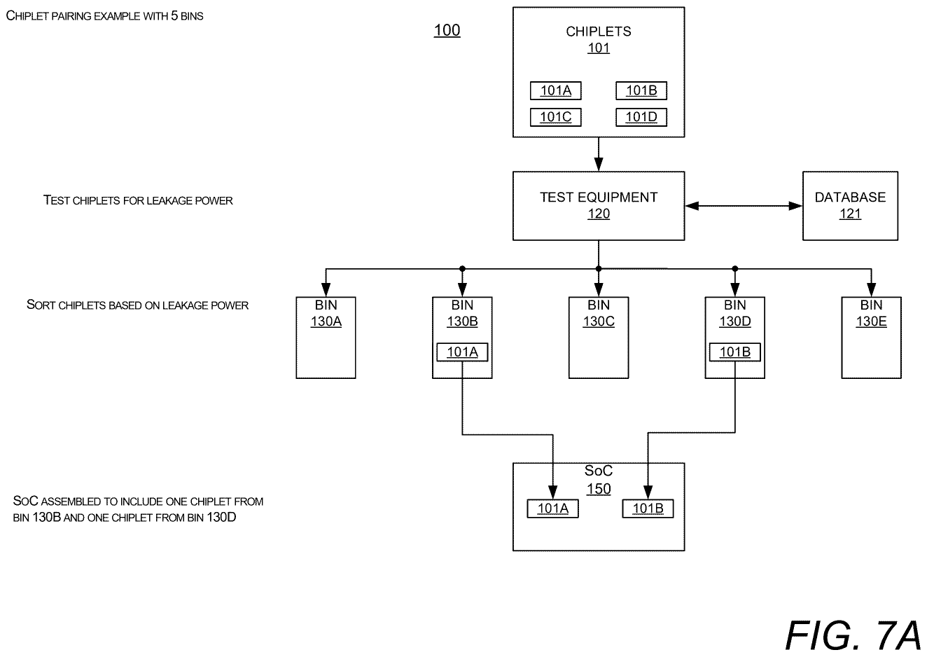

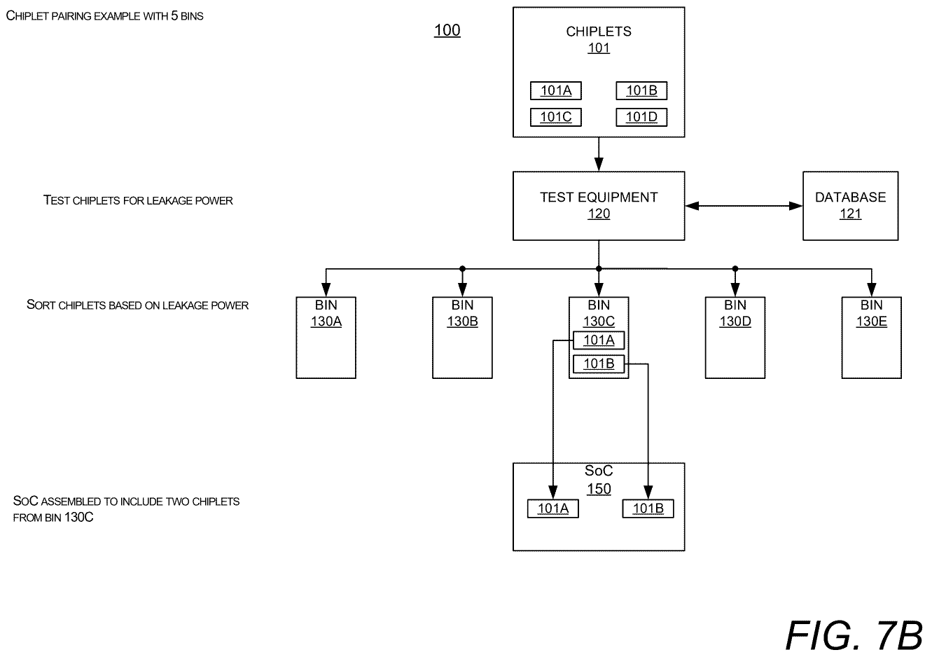

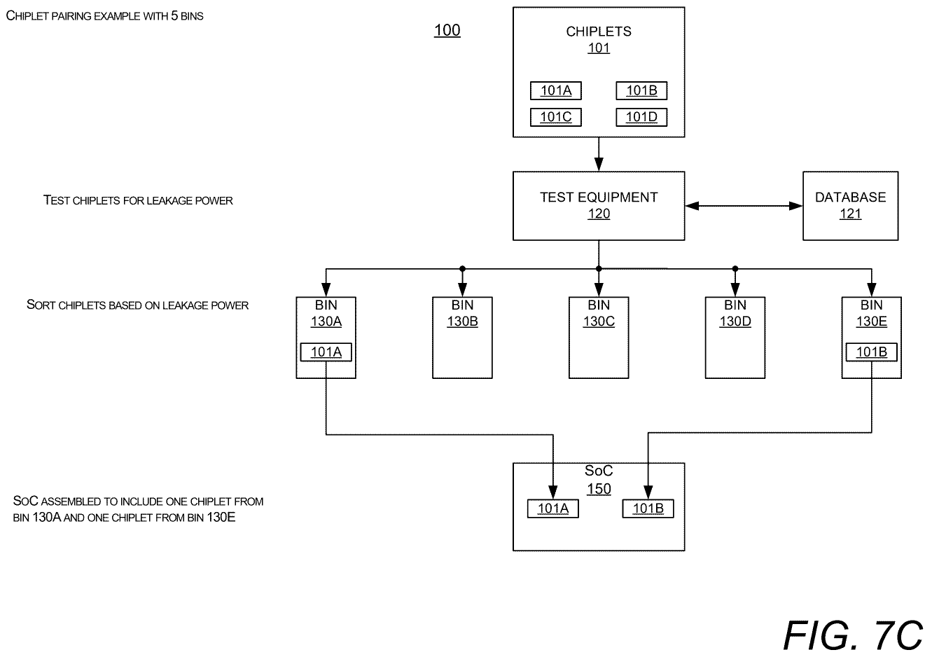

FIGS. 7A-7C show an embodiment of the process 100 in which there are five bins, with each bin as a separate category. The embodiment shown in FIGS. 7A-7C is similar to the embodiment shown in FIGS. 6A-6B, except that in FIGS. 7A-7C, there is a bin for nominal speed. Accordingly, chiplets with a very slow operating speed are placed in a first bin 130A, chiplets with a moderately slow operating speed are placed in a second bin 130B, chiplets with a nominal operating speed are placed in a third bin 130C, chiplets with a moderately fast operating speed are placed in a fourth bin 130D, and chiplets with a very fast operating speed are placed in a fifth bin 130E.

More specifically, FIG. 7A shows an example of the process 100 in which the SoC IC 150 is assembled to include one chiplet (first chiplet 101A) from the second bin 130B (which includes moderately slow chiplets) and one chiplet (second chiplet 101B) from the fourth bin 130D (which includes moderately fast chiplets). In this way, power distribution variance is reduced by pairing a chiplet with a moderate difference from the nominal speed with a chiplet having a moderate difference from the nominal speed in the opposite direction.

FIG. 7B shows an example of the process 100 in which the SoC IC 150 is assembled to include two chiplets (the first chiplet 101A and the second 101B) each from the third bin 130C (which includes nominal speed chiplets). In this way, power distribution variance is reduced by pairing a chiplet that is close to nominal speed with another chiplet that is close to nominal speed.

FIG. 7C shows an example of the process 100 in which the SoC IC 150 is assembled to include one chiplet (the first chiplet 101A) from the first bin 130A (which includes very slow chiplets) and one chiplet (the second chiplet 101B) from the fifth bin 130E (which includes very fast chiplets). In this way, power distribution variance is reduced by pairing a chiplet with a great difference from the nominal speed with a chiplet having a great difference from the nominal speed in the opposite direction.

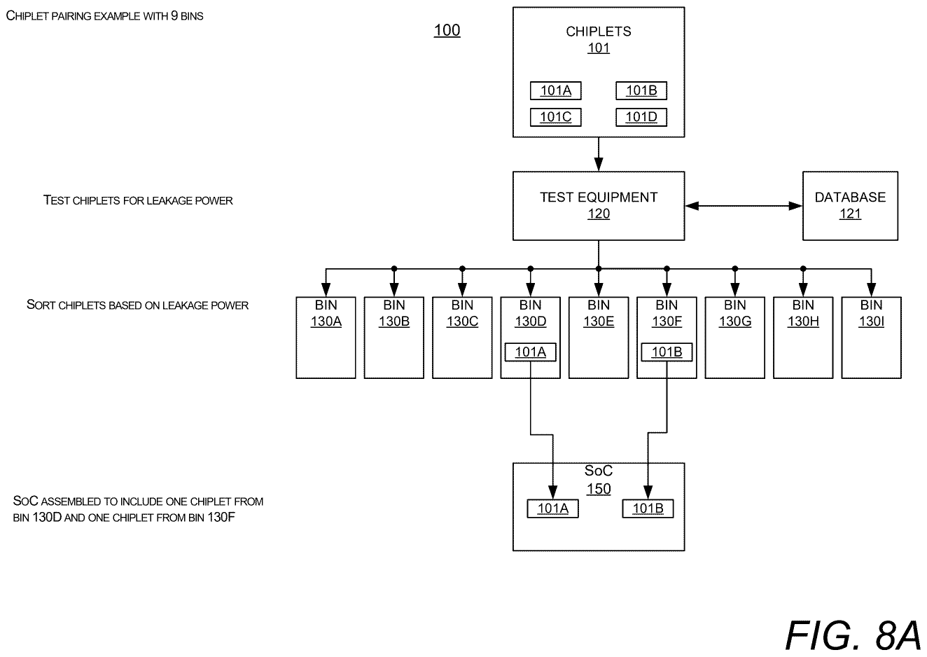

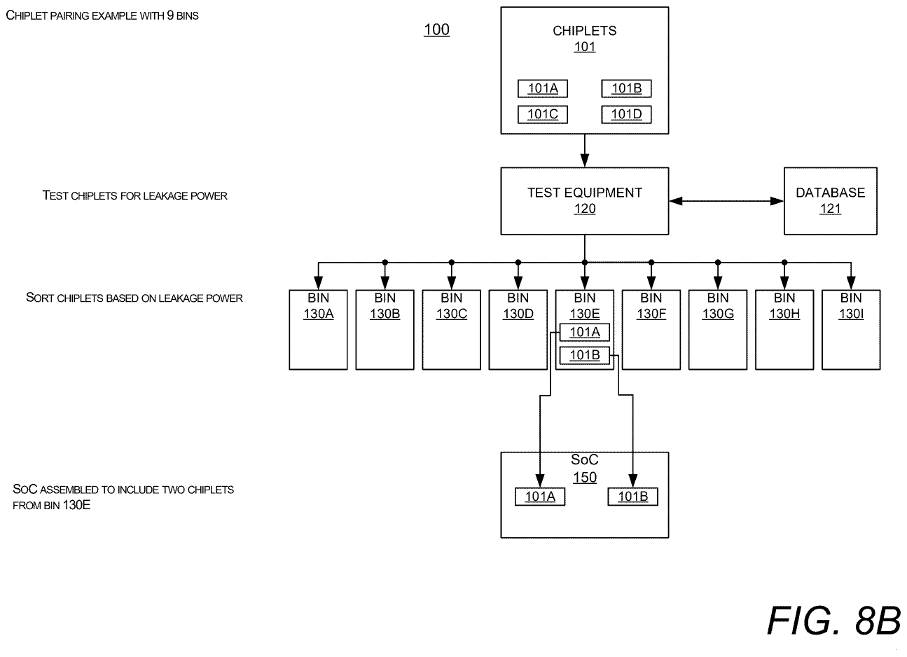

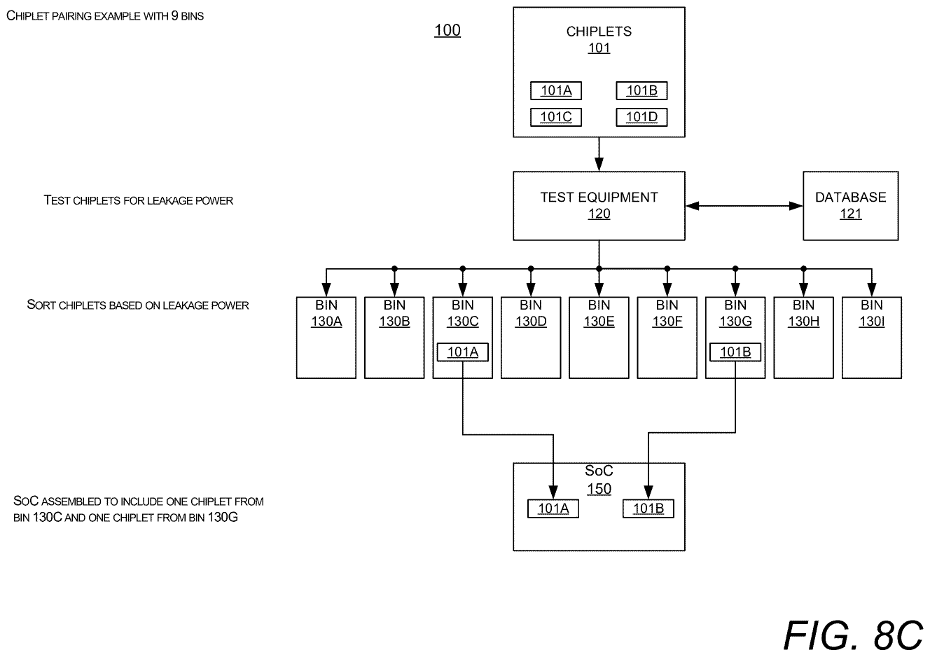

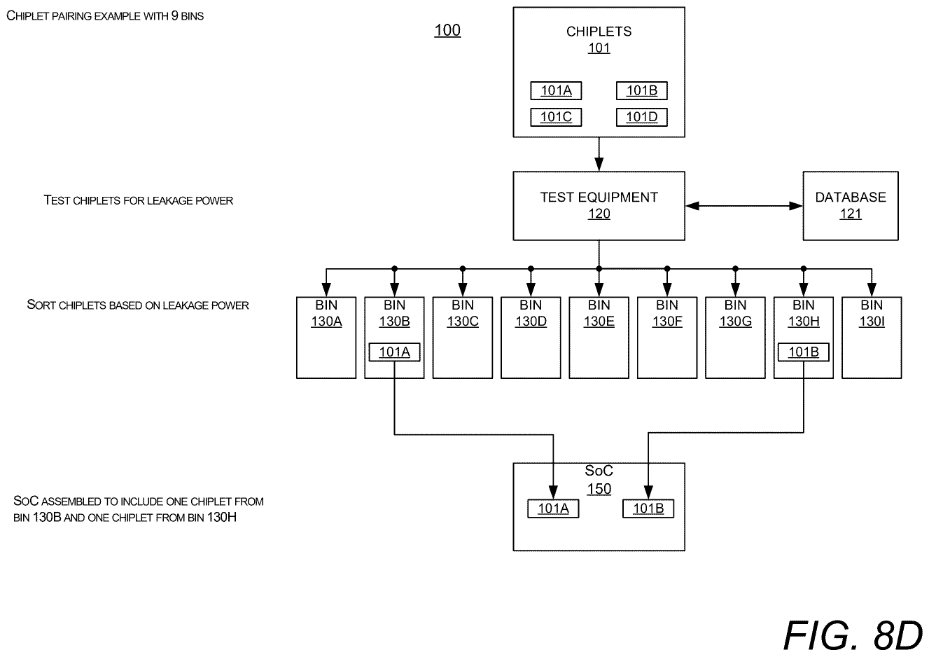

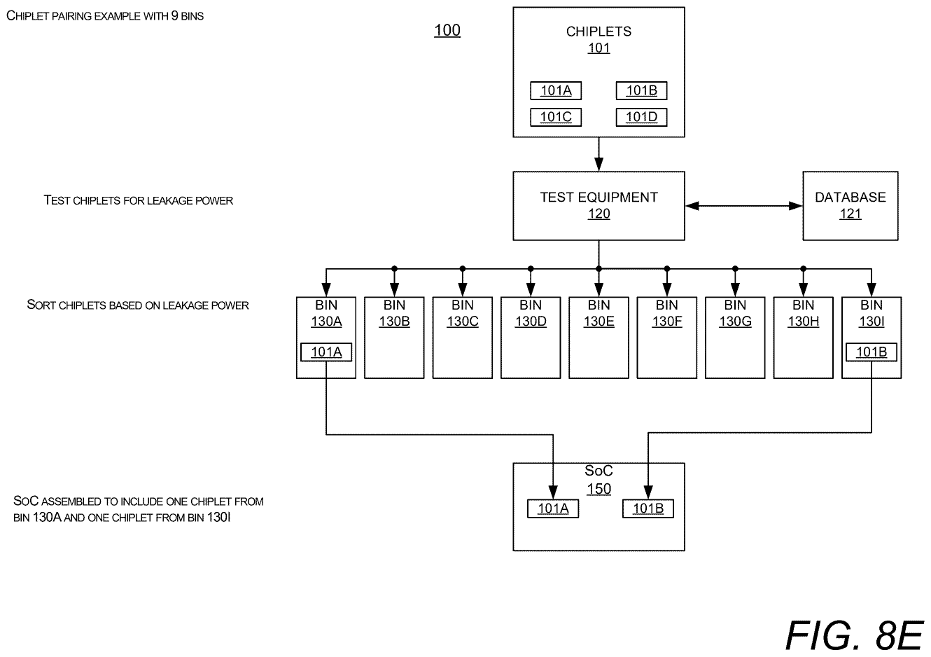

FIGS. 8A-8E show an embodiment of the process 100 in which there are nine bins 130, with each bin 130 as a separate category. In this embodiment, the nine bins 130 include a first bin 130A, a second bin 130B, a third bin 130C, a fourth bin 130D, a fifth bin 130E, a sixth bin 130F, a seventh bin 130G, an eighth bin 130H, and a ninth bin 130I. The fifth bin 130E is used for chiplets with nominal operating speed. The bins 130 are ordered by operating speed with the first bin 130A used for chiplets with the very slowest operating speeds, and the ninth bin 139 used for chiplets with the very fastest operating speeds. The ranges of operating speeds for the bins 130 are symmetrical about the nominal operating speed of a chiplet 101.

Power distribution variance is reduced by selecting chiplets from bins so that the pair is balanced with respect to the nominal operating speed. Balancing the pair with respect to the nominal operating speed causes the overall power consumption of the SoC to be balanced, so that less power allocation and capacity is required.

For instance, FIG. 8A shows an example in which the SoC IC 150 is assembled from one chiplet from the fourth bin 130D and one chiplet from the sixth bin 130F. FIG. 8B shows an example in which the SoC IC 150 is assembled from two chiplets from the fifth bin 130E, where the chiplets in the fifth bin 130E have nominal operating speeds. FIG. 8C shows an example in which the SoC IC 150 is assembled from one chiplet from the third bin 130C and one chiplet from the seventh bin 130G. FIG. 8D shows an example in which the SoC IC 150 is assembled from one chiplet from the second bin 130B and one chiplet from the eighth bin 130H. FIG. 8E shows an example in which the SoC IC 150 is assembled from one chiplet from the first bin 130A and one chiplet from the eighth bin 130I.

Accordingly, as shown in FIGS. 8A-8E, chiplets in the first bin 130A are paired with chiplets in the ninth bin 130I, chiplets in the second bin 130B are paired with chiplets in the eighth bin 130H, chiplets in the third bin 130C are paired with chiplets in the seventh bin 130G, chiplets in the fourth bin 130D are paired with chiplets in the sixth bin 130F, and chiplets in the fifth bin 130E are paired with each other. In this way, power distribution variance is reduced by selecting chiplets from bins so that the operating speeds of the pair are balanced with respect to the nominal operating speed.

The ranges to be used for the bins 130 are selected in different suitable ways in different embodiments. For example, in some embodiments, the ranges for the bins 130 are selected such that each of the bins span across the same range of voltages. In some embodiments, statistical analysis of measured data with respect to the chiplets 101, as stored in the database 121, is used to aid in the selection of the ranges for the bins 130. In some embodiments, the ranges for the bins 130 are selected using probability distribution, so that, the expected number of chiplets in each bin is the same. In some embodiments, the bins 130 that are farther from the nominal total leakage power consumption would have a smaller voltage range than bins closer to the nominal total leakage power consumption. Other suitable methods of selecting the ranges for the bins 130 are used in other embodiments. In some embodiments, the ranges for the bins 130 are selected using artificial intelligence.

In various embodiments, for chiplets that are extreme outliers in total leakage power consumption and are outside of any bin, the chiplet can be scrapped, set aside for an extreme outlier in the opposite direction, or processed in another suitable way.

The nominal total leakage power consumption or the nominal operating speed may be determined in different ways in different embodiments. In some embodiments, characterization of the distribution of speed, leakage power, and/or dynamic power of the population is used to determine the nominal leakage power consumption or the nominal operating speed of a particular type of chiplet. In some embodiments, this characterization is also used to determine the probability distribution of the operating speed or the total leakage power consumption of chiplets, and the suitable ranges to use for the bins. When dealing with a new process, the bin ranges can be adjusted after early test results are obtained.

Various embodiments given above discuss an SoC IC that is assembled using two chiplets. However, it can be appreciated that the techniques herein can be used to assemble an SoC IC with a suitable number of chiplets greater than two. For any suitable number of chiplets used to assemble the SoC IC, the chiplets can be balanced amongst each other with respect to the nominal operating speed.

For instance, for an SoC IC that is assembled with three chiplets, for example, one chiplet may be selected from a nominal speed category, one chiplet may be selected from a fast category, and one chiplet may be selected from a slow category. Other combinations, of course, are possible. For example, all three chiplets could be selected from a nominal speed category. As another example, two chiplets with a moderate difference from the nominal operating speed in one direction may be balanced against a third chiplet having a difference that is close to the sum of the difference of the other two in the opposite direction.

As another example, for an SoC IC that is assembled with four chiplets, two chiplet pairs, each balanced against each other, may be selected as the four chiplets for the SoC IC.

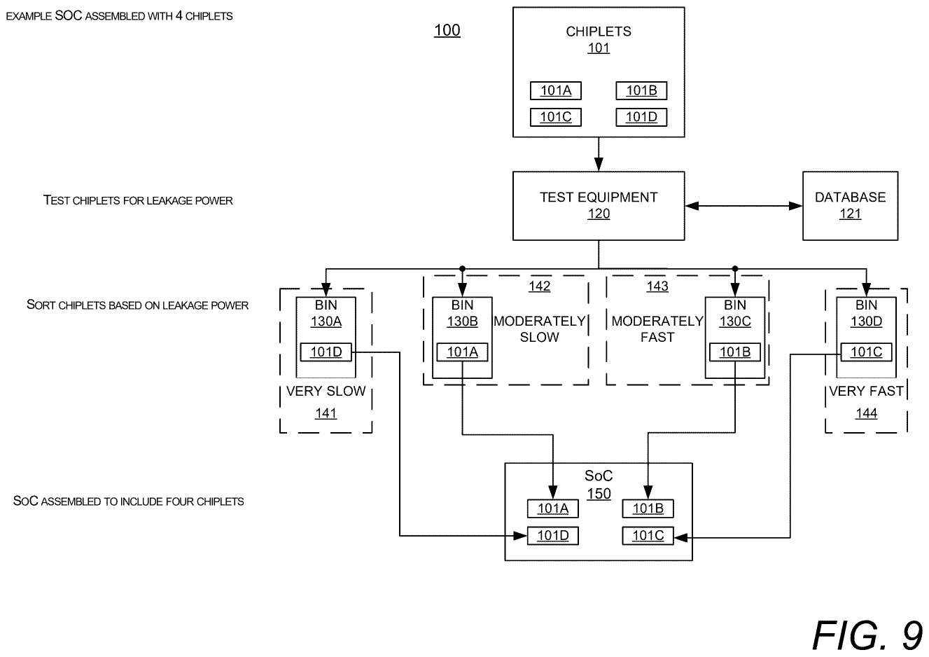

For example, FIG. 9 shows a functional block diagram of an embodiment of the process 100 for creating an SoC IC with reduced power distribution variance from four chiplets. The embodiment shown in FIG. 9 is similar to the embodiment shown in FIGS. 7A-7C, except that, in FIG. 9, the SoC IC 150 is assembled from four chiplets rather than two chiplets. The SoC IC 150 is assembled from one chiplet (the fourth chiplet 101D) from the very slow category 141, one chiplet (the first chiplet 101A) from the moderately slow category 142, one chiplet (the second chiplet 101B) from the moderately fast category 143, and one chiplet (the third chiplet 101C) from the very fast category 144.

SoC ICs (e.g., the SoC IC 150) created using the techniques discussed above may be used in many suitable applications, including server rack applications. In some embodiments, a server rack includes multiple server nodes, with each server node including an SoC IC that is created using the techniques discussed above. For instance, in some embodiments, each server node in a server rack includes one SoC IC that acts as the primary processor for the server node, managing computational workloads and resources of the server node. Some architectures may use two or more SoC ICs per server node. Also, SoC ICs may be used in portions of a server rack other than the server nodes themselves, such as power distribution units (PDUs), network switches, managements systems, or other suitable components.

While the chiplet pairing techniques discussed above can greatly reduce power variation, there may still be some power variation from SoC IC to SoC IC. This power variation can be further minimized in a datacenter at the server rack level by balancing SoC ICs in the server rack for total leakage power consumption in the same way that individual chiplets in an SoC IC are balanced for total leakage power consumption.

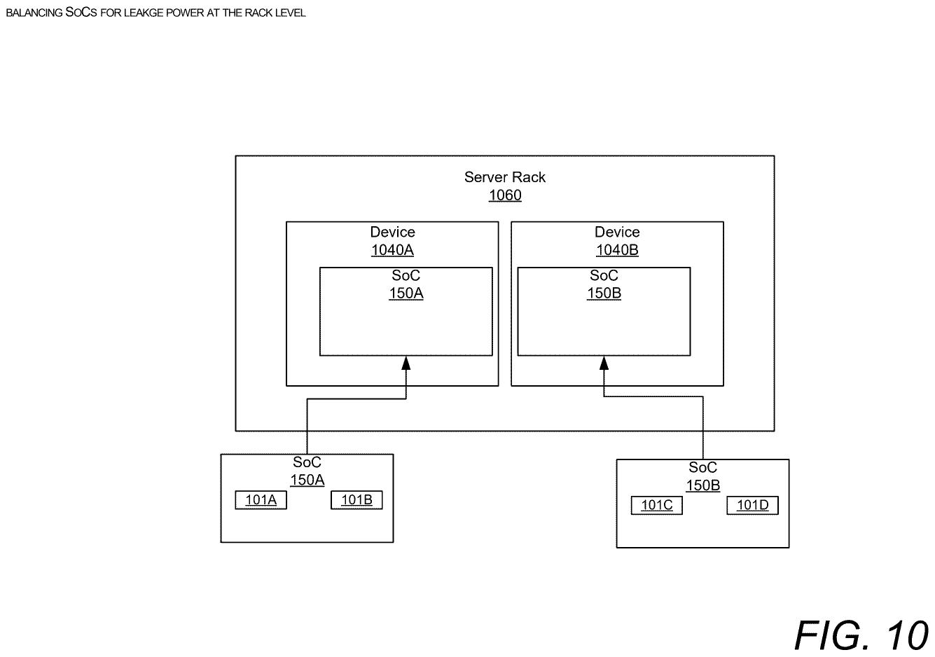

For example, FIG. 10 illustrates a block diagram of an embodiment of a server rack 1060 that is balanced with respect to leakage power consumption. The server rack 1060 includes devices 1040. For example, the devices 1040 include server nodes in some embodiments. The devices 1040 include SoC ICs 150. In the illustrated embodiment, server rack 1060 includes a first device 1040A and a second device 1040B, the first device 1040A includes a first SoC IC 150A, and the second device 1040B includes a second SoC IC 150B.

Each of the SoC ICs 150 in the server rack 1060 includes chiplets that are balanced against each other for total leakage power consumption relative to the nominal total leakage power consumption of the chiplets. The SoC ICs 150 in the server rack 1060 are balanced against each other for total leakage power consumption relative to the nominal total leakage power consumption of the SoC ICs 150.

Although FIG. 10 illustrates two devices 1040 and two SoC ICs 150, it will be appreciated that, in various embodiments, the server rack 1060 includes many more than two devices 1040 and many more than two SoC ICs 150.

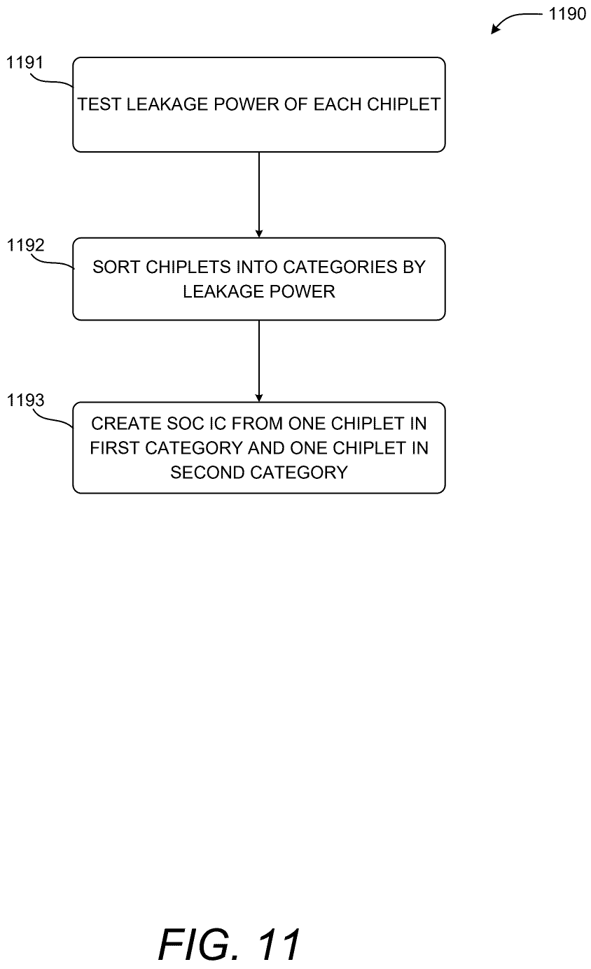

FIG. 11 is a flow diagram showing aspects of a routine 1100 for creating an SoC IC 150. The routine 1190 begins with operation 1191. At operation 1191, for each chiplet 101, a tested parameter for the chiplet 101 is determined based on a set of operating conditions. For example, the tested parameter may be a tested leakage power consumption of cores 260 on the chiplet 101, a tested dynamic power consumption of the cores 260 on the chiplet 101, or a tested operating speed of the cores 260 on the chiplet 101.

The routine then proceeds to operation 1192. At operation 1192, the chiplets 101 are categorized into categories. The categories are based on the tested parameter of the chiplets 101. The categories include a first category and a second category, such that each chiplet that is categorized in the first category has a tested parameter (e.g., a tested leakage power consumption) that is less than a nominal value (e.g., a nominal leakage power consumption), and such that each chiplet that is categorized in the second category has a tested parameter that is greater than the nominal value. The routine then proceeds to operation 1193. At operation 1193, the SoC IC 150 is created such that the SoC IC 150 includes at least one chiplet from the first category and at least one chiplet from the second category.

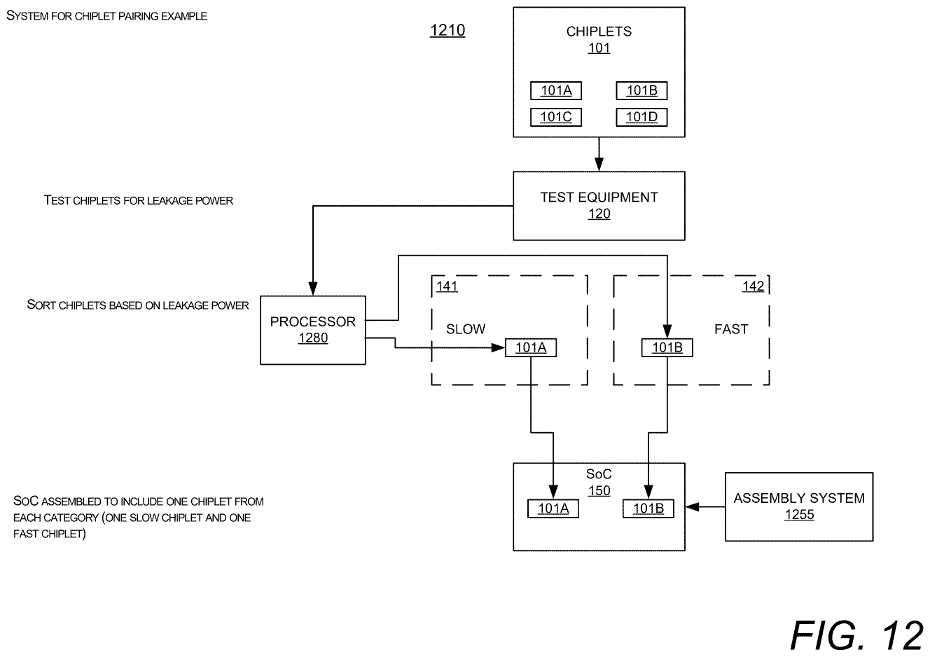

FIG. 12 illustrates a block diagram of an embodiment of a system (1210) for creating an SoC IC (150) with reduced power variation. The system 1210 includes chiplets 101, test equipment 120, a processor (1280), and an assembly system (1255). The chiplets 101 may include, for example, a first chiplet 101A, a second chiplet 101B, a third chiplet 101C, and a fourth chiplet 101D.

The test equipment 120 is configured to determine a tested leakage power consumption of cores on each of the chiplets 101. The testing of each of the chiplets 101 is done at a determined supply voltage and a determined temperature. In some embodiments, each core uses a different supply voltage, and the testing is done at a determined temperature and at a separate determined supply voltage for each of the cores. In some examples, the test equipment 120 includes an ATE unit suitable for measuring various parameters associated with the chiplets 101 and other electronic devices. The ATE unit may include hardware components such as power supplies, signal generators, and measurement instruments, as well as software to control the testing process and analyze the results.

The processor 1280 is configured to categorize each of the chiplets 101 into categories. The categories are based on the tested leakage power consumption of chiplets 101. The categories include a first category (141) and a second category (142), such that each chiplet that is categorized in the first category 141 has a tested leakage power consumption that is less than a nominal leakage power consumption, and such that each chiplet that is categorized in the second category 142 has a tested leakage power consumption that is greater than the nominal leakage power consumption. In the example illustrated, the processor 1280 categorizes the first chiplet 101A into the first category 141 and the second chiplet 101B into the second category 142. In some embodiments, the processor 1280 is part of the test equipment 120. In other embodiments, the processor 1280 is in a suitable location other than the test equipment 120. For instance, in some embodiments, the processor 1280 resides in a centralized server or cluster of servers. In some embodiments, the processor 1280 resides on remote servers that are accessed over secure networks.

The assembly system 1255 is configured to create the SoC IC 150 such that the SoC IC 150 includes at least one chiplet (e.g., the first chiplet 101A) from the first category 141 and at least one chiplet (e.g., the second chiplet 101B) from the second category 142. In some embodiments, the assembly system 1255 includes automated handling equipment, a die bonding, a wire bonding machine, an encapsulation system, or other suitable equipment, all in a cleanroom environment.

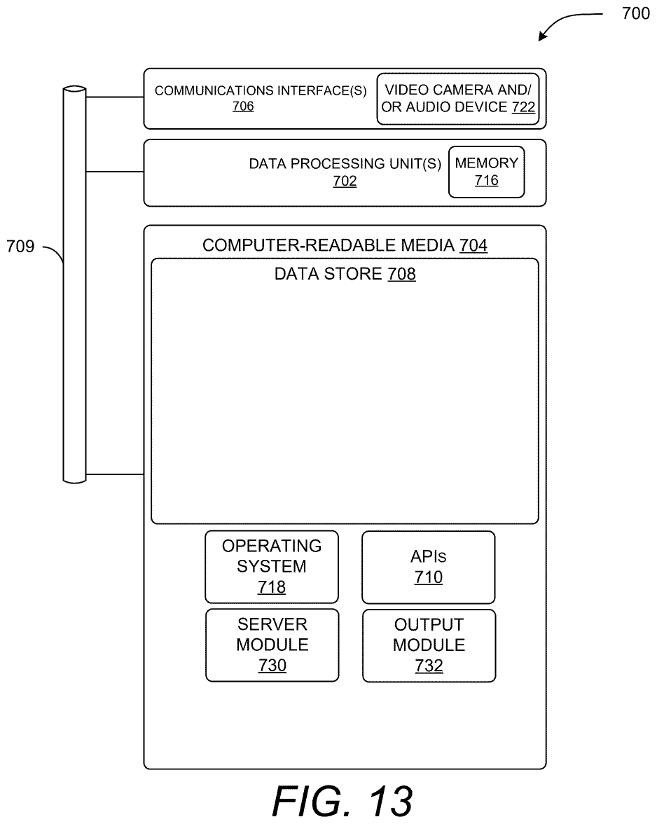

FIG. 13 is a computer architecture diagram illustrating a computing device architecture for a computing device capable of implementing aspects of the techniques and technologies presented herein. FIG. 13 illustrates a diagram that shows example components of a device 700. As illustrated, the device 700 includes one or more data processing unit(s) 702, computer-readable media 704, and communication interface(s) 706. The components of the device 700 are operatively connected, for example, via a bus 709, which may include one or more of a system bus, a data bus, an address bus, a PCI bus, a Mini-PCI bus, and any variety of local, peripheral, and/or independent buses. The one or more processing units 702 are an embodiment of the processor 1280 of FIG. 12.

As utilized herein, data processing unit(s), such as the data processing unit(s) 702, may represent, for example, a CPU-type data processing unit, a GPU-type data processing unit, a field-programmable gate array (“FPGA”), another class of DSP, or other hardware logic components that may, in some instances, be driven by a CPU. For example, and without limitation, illustrative types of hardware logic components that may be utilized include Application-Specific Integrated Circuits (“ASICs”), Application-Specific Standard Products (“ASSPs”), System-on-Chip Systems (“SOCs”), Complex Programmable Logic Devices (“CPLDs”), etc.

As utilized herein, computer-readable media, such as computer-readable media 704, may store instructions executable by the data processing unit(s). The computer-readable media may also store instructions executable by external data processing units such as by an external CPU, an external GPU, and/or executable by an external accelerator, such as an FPGA type accelerator, a DSP type accelerator, or any other internal or external accelerator. In various examples, at least one CPU, GPU, and/or accelerator is incorporated in a computing device, while in some examples one or more of a CPU, GPU, and/or accelerator is external to a computing device.

Computer-readable media, which might also be referred to herein as a computer-readable medium, may include computer storage media and/or communication media. Computer storage media may include one or more of volatile memory, nonvolatile memory, and/or other persistent and/or auxiliary computer storage media, removable and non-removable computer storage media implemented in any method or technology for storage of information such as computer-readable instructions, data structures, program modules, or other data. Thus, computer storage media includes tangible and/or physical forms of media included in a device and/or hardware component that is part of a device or external to a device, including but not limited to random access memory (“RAM”), static random-access memory (“SRAM”), dynamic random-access memory (“DRAM”), phase change memory (“PCM”), read-only memory (“ROM”), erasable programmable read-only memory (“EPROM”), electrically erasable programmable read-only memory (“EEPROM”), flash memory, compact disc read-only memory (“CD-ROM”), digital versatile disks (“DVDs”), optical cards or other optical storage media, magnetic cassettes, magnetic tape, magnetic disk storage, magnetic cards or other magnetic storage devices or media, solid-state memory devices, storage arrays, network attached storage, storage area networks, hosted computer storage or any other storage memory, storage device, and/or storage medium that can be used to store and maintain information for access by a computing device. The computer storage media can also be referred to herein as computer-readable storage media, non-transitory computer-readable storage media, non-transitory computer-readable medium, computer-readable storage medium, computer-readable storage device, or computer storage medium.

In contrast to computer storage media, communication media may embody computer-readable instructions, data structures, program modules, or other data in a modulated data signal, such as a carrier wave, or other transmission mechanism. As defined herein, computer storage media does not include communication media. That is, computer storage media does not include communications media consisting solely of a modulated data signal, a carrier wave, or a propagated signal, per se.

Communication interface(s) 706 may represent, for example, network interface controllers (“NICs”) or other types of transceiver devices to send and receive communications over a network. Furthermore, the communication interface(s) 706 may include one or more video cameras and/or audio devices 722 to enable generation of video feeds and/or still images, and so forth.

In the illustrated example, computer-readable media 704 includes a data store 708. In some examples, the data store 708 includes data storage such as a database, data warehouse, or other type of structured or unstructured data storage. In some embodiments, the data store 708 includes an example of the database 121. In some examples, the data store 708 includes a corpus and/or a relational database with one or more tables, indices, stored procedures, and so forth to enable data access including one or more of hypertext markup language (“HTML”) tables, resource description framework (“RDF”) tables, web ontology language (“OWL”) tables, and/or extensible markup language (“XML”) tables, for example. The data store 708 may store data for the operations of processes, applications, components, and/or modules stored in computer-readable media 704 and/or executed by data processing unit(s) 702 and/or accelerator(s).

Alternately, some or all of the above-referenced data can be stored on separate memories 716 on board one or more data processing unit(s) 702 such as a memory on board a CPU-type processor, a GPU-type processor, an FPGA-type accelerator, a DSP-type accelerator, and/or another accelerator. In this example, the computer-readable media 704 also includes an operating system 718 and application programming interface(s) 710 (APIs) configured to expose the functionality and the data of the device 700 to other devices. Additionally, the computer-readable media 704 includes one or more modules such as a server module (730) and an output module (732), although the number of illustrated modules is just an example, and the number may vary. That is, functionality described herein in association with the illustrated modules may be performed by a fewer number of modules or a larger number of modules on one device or spread across multiple devices.

The present disclosure is supplemented with the following clauses:
Clause A. A method for creating, e.g., a method of manufacturing, a system-on-chip (SoC) integrated circuit (IC) (150), the method comprising: performing pre-binning on a plurality of chiplets (101), the pre-binning comprising: for each chiplet of the plurality of chiplets (101): determining a tested parameter, wherein the tested parameter is at least one of: a leakage power consumption (P_{LEAKAGE}) of cores (260) on the chiplet, a dynamic power consumption of the cores (260) on the chiplet, or an operating speed of the cores (260) on the chiplet, based on a determined set of operating conditions; and categorizing the chiplets of the plurality of chiplets (101) into a plurality of categories, wherein the plurality of categories is based on the tested parameter of the chiplets in the plurality of chiplets (101), and wherein the plurality of categories comprises a first category (141) and a second category (142), such that each chiplet that is categorized in the first category (141) has a tested parameter that is less than a nominal value, and such that each chiplet that is categorized in the second category (142) has a tested parameter that is greater than the nominal value; and creating the SoC IC (150) such that the SoC IC (150) comprises at least one chiplet (101A) from the first category (141) and at least one chiplet (101D) from the second category (142).
Clause B: The method of Clause A, wherein determining the tested parameter on the chiplet comprises: measuring an oscillation frequency (F_{RING}) of a ring oscillator (170) on the chiplet.
Clause C: the method of Clauses A-B, wherein determining the tested parameteron the chiplet comprises measuring an output of a proxy on the chiplet.
Clause D: The method of Clauses A-C, wherein the determined set of operating conditions comprises a determined supply voltage (VDD) and a determined temperature.
Clause E: The method of Clause D, wherein determining the tested parameter on the chiplet comprises: for each of the cores (260) on the chiplet, measuring a leakage current of the core (260); for each of the cores (260) on the chiplet, determining the leakage power consumption of the core by multiplying the measured leakage current of the core by the determined supply voltage (VDD); and determining the leakage power consumption (P_{LEAKAGE}) of the cores (260) on the chiplet by adding together the determined leakage power consumption of each of the cores (260) on the chiplet.
Clause F: The method of Clauses A-E, further comprising: creating a plurality of additional SoC ICs, wherein at least two of the additional SoC ICs comprise at least one chiplet from the first category and at least one chiplet from the second category.
Clause G: The method of Clause F, further comprising: deploying the plurality of additional SoC IPs on a server rack; and balancing power consumption across the server rack based on the categorization of the chiplets in each of the SoC ICs in the plurality of additional SoC ICs.
Clause H: The method of Clause F-G, wherein the plurality of categories further comprises a third category, such that chiplets in the third category have a tested parameter that is approximately equal to the nominal value, and wherein creating the plurality of additional SoC ICs further comprises: creating at least one SoC IC comprising at least two chiplets from the third category.
Clause I: The method of Clause H, wherein the first category of chiplets comprises chiplets having a tested parameter moderately below the nominal value, the second category of chiplets comprises chiplets having a tested parameter moderately above the nominal value, and wherein the plurality of chiplets further comprises a fourth category and a fifth category, such that chiplets in the fourth category have a tested parameter that is substantially below the nominal value, and such that chiplets in the fifth category have a tested parameter that is substantially above the nominal value.
Clause J: The method of Clause I, wherein creating the plurality of additional SoC ICs further comprises: creating at least one SoC IC of the plurality of SoC ICs such that the SoC IC comprises at least one chiplet from the fourth category and at least one chiplet from the fifth category.
Clause K. A system (1210) for creating a system-on-chip (SoC) integrated circuit (IC) (150) the system, comprising: a plurality of chiplets (101); test equipment (120) that is configured to determine a tested parameter, wherein the tested parameter is at least one of: leakage power consumption (P_{LEAKAGE}) of cores (260) on each chiplet of the plurality of chiplets (101), a dynamic power consumption of the cores (260) on the chiplet, or an operating speed of the cores (260) on the chiplet, based on a determined supply voltage and a determined temperature; a processor (1280) that is configured to categorize each of the chiplets of the plurality of chiplets (101) into a plurality of categories, wherein the plurality of categories is based on the tested parameter of the chiplets in the plurality of chiplets (101), and wherein the plurality of categories comprises a first category (141) and a second category (142), such that each chiplet that is categorized in the first category (141) has a tested parameter that is less than a nominal value, and such that each chiplet that is categorized in the second category (142) has a tested parameter that is greater than the nominal value; and an assembly system (1255) that is configured to create the SoC IC (150) such that the SoC IC (150) comprises at least one chiplet (101A) from the first category (141) and at least one chiplet (101D) from the second category (142).
Clause L: The system of Clause K, wherein the test equipment is further configured such that determining the tested parameter on the chiplet comprises: measuring an oscillation frequency (F_{RING}) of a ring oscillator (170) on the chiplet.
Clause M: the method of Clauses K-L, wherein the test equipment is further configured such that determining the tested parameter on the chiplet comprises measuring an output of a proxy on the chiplet.
Clause N: the method of Clauses K-M, wherein the test equipment is further configured such that determining the tested parameter on the chiplet comprises: for each of the cores (260) on the chiplet, measuring a leakage current of the core (260); for each of the cores (260) on the chiplet, determining the leakage power consumption of the core by multiplying the measured leakage current of the core by the determined supply voltage (VDD); and determining the leakage power consumption (P_{LEAKAGE}) of the cores (260) on the chiplet by adding together the determined leakage power consumption of each of the cores (260) on the chiplet.
Clause O. A method for creating a system-on-chip (SoC) integrated circuit (IC) (150), the method comprising: performing pre-binning on a plurality of dies (101), the pre-binning comprising: for each die of the plurality of dies (101): determining a tested parameter, wherein the tested parameter includes at least one of: leakage power consumption (P_{LEAKAGE}) of cores (260) on the die, a dynamic power consumption of the cores (260) on the die, or an operating speed of the cores (260) on the die, based on a determined set of operating conditions; and sorting the dies of the plurality of dies (101) into a plurality of categories, wherein the plurality of categories is based on the tested parameter of the dies in the plurality of dies (101), and wherein the plurality of categories comprises a first category (141) and a second category (142), such that each die that is sort into the first category (141) has a tested parameter that is less than a nominal value, and such that each die that is sorted into the second category (142) has a tested parameter that is greater than the nominal value; and creating the SoC IC (150) such that the SoC IC (150) comprises at least two dies of the plurality of dies such that the at least two dies are balanced against each other with respect to the nominal leakage power consumption, and such that the at least two dies include at least one die (101A) from the first category (141) and at least one die (101D) from the second category (142).
Clause P: The method of Clause O, wherein the at least two dies further comprise a third die.
Clause Q: The method of Clause P, wherein the at least two dies further comprise a fourth die.
Clause R: The method of Clauses K-Q, further comprising: creating a plurality of additional SoC ICs, wherein at least two of the additional SoC ICs comprise at least one die from the first category and at least one die from the second category, and wherein the plurality of categories further comprises a third category, such that chiplets in the third category have a tested parameter that is approximately equal to the nominal value, and wherein creating the plurality of additional SoC ICs further comprises creating at least one SoC IC comprising at least two chiplets from the third category.
Clause S: The method of Clause R, wherein the first category of chiplets comprises chiplets having a tested parameter moderately below the nominal value, the second category of chiplets comprises chiplets having a tested parameter moderately above the nominal value, and wherein the plurality of chiplets further comprises a fourth category and a fifth category, such that chiplets in the fourth category have a tested parameter that is substantially below the nominal value, and such that chiplets in the fifth category have a tested parameter that is substantially above the nominal value.
Clause T: The method of Clause S, wherein creating the plurality of additional SoC ICs further comprises: creating at least one SoC IC of the plurality of SoC ICs such that the SoC IC comprises at least one chiplet from the fourth category and at least one chiplet from the fifth category.

In closing, although the various configurations have been described in language specific to structural features and/or methodological acts, it is to be understood that the subject matter defined in the appended representations is not necessarily limited to the specific features or acts described. Rather, the specific features and acts are disclosed as example forms of implementing the claimed subject matter.

What is claimed is:

1. A method for creating a system-on-chip (SoC) integrated circuit (IC), the method comprising:
performing pre-binning on a plurality of chiplets, the pre-binning comprising:
for each chiplet of the plurality of chiplets: determining a tested parameter, wherein the tested parameter is at least one of: a leakage power consumption of cores on the chiplet, a dynamic power consumption of the cores on the chiplet, or an operating speed of the cores on the chiplet, based on a determined set of operating conditions; and
categorizing the chiplets of the plurality of chiplets into a plurality of categories, wherein the plurality of categories is based on the tested parameter of the chiplets in the plurality of chiplets, and wherein the plurality of categories comprises a first category and a second category, such that each chiplet that is categorized in the first category has a tested parameter that is less than a nominal value, and such that each chiplet that is categorized in the second category has a tested parameter that is greater than the nominal value; and
creating the SoC IC such that the SoC IC comprises at least one chiplet from the first category and at least one chiplet from the second category.

2. The method of claim 1, wherein determining the tested parameter on the chiplet comprises:
measuring an oscillation frequency of a ring oscillator on the chiplet.

3. The method of claim 1, wherein determining the tested parameter on the chiplet comprises measuring an output of a proxy on the chiplet.

4. The method of claim 1, wherein the determined set of operating conditions comprises a determined supply voltage and a determined temperature.

5. The method of claim 4, wherein determining the tested parameter on the chiplet comprises:
for each of the cores on the chiplet, measuring a leakage current of the core;
for each of the cores on the chiplet, determining the leakage power consumption of the core by multiplying the measured leakage current of the core by the determined supply voltage; and
determining the leakage power consumption of the cores on the chiplet by adding together the determined leakage power consumption of each of the cores on the chiplet.

6. The method of claim 1, further comprising:
creating a plurality of additional SoC ICs, wherein at least two of the additional SoC ICs comprise at least one chiplet from the first category and at least one chiplet from the second category.

7. The method of claim 6, further comprising:
deploying the plurality of additional SoC IPs on a server rack; and
balancing power consumption across the server rack based on the categorization of the chiplets in each of the SoC ICs in the plurality of additional SoC ICs.

8. The method of claim 6, wherein the plurality of categories further comprises a third category, such that chiplets in the third category have a tested parameter that is approximately equal to the nominal value, and wherein creating the plurality of additional SoC ICs further comprises:
creating at least one SoC IC comprising at least two chiplets from the third category.

9. The method of claim 8, wherein the first category of chiplets comprises chiplets having a tested parameter moderately below the nominal value, the second category of chiplets comprises chiplets having a tested parameter moderately above the nominal value, and wherein the plurality of chiplets further comprises a fourth category and a fifth category, such that chiplets in the fourth category have a tested parameter that is substantially below the nominal value, and such that chiplets in the fifth category have a tested parameter that is substantially above the nominal value.

10. The method of claim 9, wherein creating the plurality of additional SoC ICs further comprises:
creating at least one SoC IC of the plurality of SoC ICs such that the SoC IC comprises at least one chiplet from the fourth category and at least one chiplet from the fifth category.

11. A system for creating a system-on-chip (SoC) integrated circuit (IC), the system comprising:
a plurality of chiplets;
test equipment that is configured to determine a tested parameter, wherein the tested parameter is at least one of: a leakage power consumption of cores on each chiplet of the plurality of chiplets, a dynamic power consumption of the cores on the chiplet, or an operating speed of the cores on the chiplet, based on a determined supply voltage and a determined temperature;
a processor that is configured to categorize each of the chiplets of the plurality of chiplets into a plurality of categories, wherein the plurality of categories is based on the tested parameter of the chiplets in the plurality of chiplets, and wherein the plurality of categories comprises a first category and a second category, such that each chiplet that is categorized in the first category has a tested parameter that is less than a nominal value, and such that each chiplet that is categorized in the second category has a tested parameter that is greater than the nominal value; and
an assembly system that is configured to create the SoC IC such that the SoC IC comprises at least one chiplet from the first category and at least one chiplet from the second category.

12. The system of claim 11, wherein the test equipment is further configured such that determining the tested parameter on the chiplet comprises:
measuring an oscillation frequency of a ring oscillator on the chiplet.

13. The system of claim 11, wherein the test equipment is further configured such that determining the tested parameter on the chiplet comprises measuring an output of a proxy on the chiplet.

14. The system of claim 11, wherein the test equipment is further configured such that determining the tested parameter on the chiplet comprises:
for each of the cores on the chiplet, measuring a leakage current of the core;
for each of the cores on the chiplet, determining the leakage power consumption of the core by multiplying the measured leakage current of the core by the determined supply voltage; and
determining the leakage power consumption of the cores on the chiplet by adding together the determined leakage power consumption of each of the cores on the chiplet.

15. A method for creating a system-on-chip (SoC) integrated circuit (IC), the method comprising:
performing pre-binning on a plurality of dies, the pre-binning comprising:
for each die of the plurality of dies: determining a tested parameter, wherein the tested parameter includes at least one of: a leakage power consumption of cores on the die, a dynamic power consumption of the cores on the die, or an operating speed of the cores on the die, based on a determined set of operating conditions; and
sorting the dies of the plurality of dies into a plurality of categories, wherein the plurality of categories is based on the tested parameter of the dies in the plurality of dies, and wherein the plurality of categories comprises a first category and a second category, such that each die that is sort into the first category has a tested parameter that is less than a nominal value, and such that each die that is sorted into the second category has a tested parameter that is greater than the nominal value; and
creating the SoC IC such that the SoC IC comprises at least two dies of the plurality of dies such that the at least two dies are balanced against each other with respect to the nominal value, and such that the at least two dies include at least one die from the first category and at least one die from the second category.

16. The method of claim 15, wherein the at least two dies further comprise a third die.

17. The method of claim 16, wherein the at least two dies further comprise a fourth die.

18. The method of claim 15, further comprising:
creating a plurality of additional SoC ICs, wherein at least two of the additional SoC ICs comprise at least one die from the first category and at least one die from the second category, and wherein the plurality of categories further comprises a third category, such that chiplets in the third category have a tested parameter that is approximately equal to the nominal value, and wherein creating the plurality of additional SoC ICs further comprises creating at least one SoC IC comprising at least two chiplets from the third category.

19. The method of claim 18, wherein the first category of chiplets comprises chiplets having a tested parameter moderately below the nominal value, the second category of chiplets comprises chiplets having a tested parameter moderately above the nominal value, and wherein the plurality of chiplets further comprises a fourth category and a fifth category, such that chiplets in the fourth category have a tested parameter that is substantially below the nominal value, and such that chiplets in the fifth category have a tested parameter that is substantially above the nominal value.

20. The method of claim 19, wherein creating the plurality of additional SoC ICs further comprises:
creating at least one SoC IC of the plurality of SoC ICs such that the SoC IC comprises at least one chiplet from the fourth category and at least one chiplet from the fifth category.
